(19) United States
(12) Patent Application Publication
(10) Pub. No.: US 2020/0052667 A1
(43) Pub. Date: Feb. 13, 2020

(54) MOBILE TERMINAL AND CONTROL METHOD THEREOF

(71) Applicant: LG ELECTRONICS INC., Seoul (KR)

(72) Inventors: Jaebeom JEON, Seoul (KR); Kyungdong CHOI, Seoul (KR)

(73) Assignee: LG ELECTRONICS INC., Seoul (KR)

(21) Appl. No.: 16/344,573

(22) PCT Filed: Nov. 11, 2016
(86) PCT No.: PCT/KR2016/012987

§ 371 Date: Apr. 24, 2019

(30) Foreign Application Priority Data
Nov. 1, 2016 (KR) 10-2016-0144198

(51) Int. Cl. H03G 3/04; H04R 1/08; H04M 1/03; H04M 1/02; G06F 3/0488; G06F 3/0484

(52) U.S. Cl. CPC H03G 3/04; H04R 1/083; H04M 1/035; H04R 2499/11; G06F 3/0488; G06F 3/04845; H04M 1/0202

(57) ABSTRACT

A mobile terminal according to one embodiment of the present invention comprises: a display unit for displaying a screen of a recording application; a voice signal input unit for receiving a voice signal according to a recording command; and a control unit, wherein the control unit displays an image corresponding to each of a plurality of sound sources on the screen when the voice signal includes the voice signal of the plurality of sound sources, controls the display unit to display a specific indicator associated with a change in a set value of the recording application on the screen, senses a touch input for moving the specific indicator, changes the set value so that the magnitude of the voice signal of a sound source corresponding to an image that is getting farther from the specific indicator among the images corresponding to each of the plurality of sound sources becomes smaller after the specific indicator moves, and changes the set value so that the magnitude of the voice signal of a sound source corresponding to an image that is getting closer to the specific indicator among the images corresponding to each of the plurality of sound sources becomes larger after the specific indicator moves.

### TECHNICAL FIELD

The present invention relates to a mobile terminal and controlling method thereof.

### BACKGROUND ART

Terminals may be generally classified as mobile/portable terminals or stationary terminals according to their mobility. Mobile terminals may also be classified as handheld terminals or vehicle mounted terminals according to whether or not a user can directly carry the terminal.

A mobile terminal is a device which may be configured to perform various functions. Examples of such functions include data and voice communications, capturing images and video via a camera, recording audio, playing music files and outputting music via a speaker system, and displaying images and video on a display. Some terminals include additional functionality which supports game playing, while other terminals are also configured as multimedia players. More recently, mobile terminals have been configured to receive broadcast and multicast signals which permit viewing of contents, such as videos and television programs.

Some mobile terminals include additional functionality which supports game playing, while other terminals are configured as multimedia players. More recently, mobile terminals have been configured to receive broadcast and multicast signals which permit viewing of content such as videos and television programs.

To support and increase the mobile terminal functions, it may be able to consider the improvement of structural parts and/or software parts of the mobile terminal.

Recently, a mobile terminal on which a recording application of performing a function specialized for recording experts is installed is released. Yet, there is a problem that the recording application of performing the specialized function is difficult to use unless an expert.

Meanwhile, a recording application lacks a variety of usability and user convenience in comparison to a play function of a music and video application. Hence, it is increasingly necessary to complement a recording function.

Therefore, the demand for developing a mobile terminal and control method thereof is rising to solve the above problems of the related art mobile terminal.

### DISCLOSURE OF THE INVENTION

### Technical Tasks

One object of the present invention is to solve the aforementioned problems and other problems. One technical task of one embodiment of the present invention is to enable an ordinary person to easily use a function specialized for recording experts.

Another technical task of one embodiment of the present invention is to enhance usability and user convenience of a recording application.

Technical tasks obtainable from the present invention are non-limited by the above-mentioned technical tasks. And, other unmentioned technical tasks can be clearly understood from the following description by those having ordinary skill in the technical field to which the present invention pertains.

### Technical Solution

In one technical aspect of the present invention, provided herein is a mobile terminal, including a display unit configured to display a screen of a recording application, an audio signal input unit configured to receive an input of an audio signal in response to a recording command, and a controller configured to display an image corresponding to each of a plurality of sound sources on the screen when the audio signal includes audio signals of the sound sources, control the display unit to display a specific indicator related to a change of a setting value of the recording application on the screen, detect a touch input of moving the specific indicator, change the setting value so as to decrease a size of an audio signal of a sound source corresponding to an image getting away from the specific indicator among images respectively corresponding to the sound sources after movement of the specific indicator, and change the setting value so as to increase a size of an audio signal of a sound source corresponding to an image getting closer to the specific indicator among the images respectively corresponding to the sound sources after the movement of the specific indicator.

Technical solutions obtainable from the present invention are non-limited by the above-mentioned technical solutions. And, other unmentioned solutions can be clearly understood from the following description by those having ordinary skill in the technical field to which the present invention pertains.

### Advantageous Effects

Effects of a mobile terminal and control method thereof according to the present invention are described as follows.

According to at least one of embodiments of the present, an ordinary person can advantageously use a function specialized for recording experts with ease.

According to at least one of embodiments of the present, usability and user convenience of a recording application can be advantageously enhanced.

Effects obtainable from the present invention are non-limited by the above-mentioned effects. And, other unmentioned effects can be clearly understood from the following description by those having ordinary skill in the technical field to which the present invention pertains.

### DESCRIPTION OF DRAWINGS

FIG. 1A is a block diagram to describe a mobile terminal related to the present invention.

FIG. 1B and FIG. 1C are conceptual diagrams for one example of a mobile terminal related to the present invention in different views.

FIG. 2 is a conceptual view of a deformable mobile terminal according to an alternative embodiment of the present disclosure.

FIG. 3 is a conceptual view of a wearable mobile terminal according to another alternative embodiment of the present disclosure.

FIG. 4 is a conceptual view of a wearable mobile terminal according to another alternative embodiment of the present disclosure.

FIG. 5 is a block diagram showing configuration modules of a mobile terminal according to one embodiment of the present invention.

FIG. 6 is a diagram to describe a mobile terminal having a plurality of microphones.

FIG. 7 is a diagram to describe one example of a running screen of a recording application according to one embodiment of the present invention.

FIG. 8 is a diagram to describe another example of a running screen of a recording application according to one embodiment of the present invention.

FIG. 9 is a diagram to describe one example of a method of recognizing information on a sound source in a mobile terminal according to one embodiment of the present invention.

FIG. 10 is a diagram to describe one example of a method of recognizing a location of each of a plurality of sound sources in a mobile terminal according to one embodiment of the present invention.

FIG. 11 is a diagram to describe one example of a method of displaying information on a sound source in a mobile terminal according to one embodiment of the present invention.

FIG. 12 is a diagram to describe one example of a method of moving a specific indicator for changing a setting value of a recording application in a mobile terminal according to one embodiment of the present invention.

FIG. 13 and FIG. 14 are diagrams to describe one example of a method of changing a setting value of a recording application to change a size of an audio signal of each of a plurality of sound sources in a mobile terminal according to one embodiment of the present invention.

FIG. 15 is a diagram to describe one example of a method of changing a setting value of a recording application to correspond to a length of a touch input of a specific indicator in a mobile terminal according to one embodiment of the present invention.

FIG. 16 is a diagram to describe one example of a method of displaying information on a setting value changed in response to a movement of a location of a specific indicator in a mobile terminal according to one embodiment of the present invention.

FIG. 17 is a diagram to describe another example of a running screen of a recording application in a mobile terminal according to one embodiment of the present invention.

FIG. 18 is a diagram to describe one example of a method of changing a setting value for an audio signal of a specific sound source in a mobile terminal according to one embodiment of the present invention.

FIG. 19 is a diagram to describe one example of a method of changing a setting of a recording application through a setting change menu of a recording application in a mobile terminal according to one embodiment of the present invention.

FIG. 20 and FIG. 21 are diagrams to describe examples of a method of launching a recording application in a deactivated state of a display unit in a mobile terminal according to one embodiment of the present invention.

FIG. 22 is a flowchart to describe one example of a method of changing a setting value of a recording application in a mobile terminal according to one embodiment of the present invention.

### MODE FOR INVENTION

Description will now be given in detail according to exemplary embodiments disclosed herein, with reference to the accompanying drawings. For the sake of brief description with reference to the drawings, the same or equivalent components may be provided with the same reference numbers, and description thereof will not be repeated. In general, a suffix such as “module” and “unit” may be used to refer to elements or components. Use of such a suffix herein is merely intended to facilitate description of the specification, and the suffix itself is not intended to give any special meaning or function. In the present disclosure, that which is well-known to one of ordinary skill in the relevant art has generally been omitted for the sake of brevity. The accompanying drawings are used to help easily understand various technical features and it should be understood that the embodiments presented herein are not limited by the accompanying drawings. As such, the present disclosure should be construed to extend to any alterations, equivalents and substitutes in addition to those which are particularly set out in the accompanying drawings.

It will be understood that although the terms first, second, etc. may be used herein to describe various elements, these elements should not be limited by these terms. These terms are generally only used to distinguish one element from another.

It will be understood that when an element is referred to as being “connected with” another element, the element can be connected with the other element or intervening elements may also be present. In contrast, when an element is referred to as being “directly connected with” another element, there are no intervening elements present.

A singular representation may include a plural representation unless it represents a definitely different meaning from the context.

Terms such as “include” or “has” are used herein and should be understood that they are intended to indicate an existence of several components, functions or steps, disclosed in the specification, and it is also understood that greater or fewer components, functions, or steps may likewise be utilized.

Mobile terminals presented herein may be implemented using a variety of different types of terminals. Examples of such terminals include cellular phones, smart phones, user equipment, laptop computers, digital broadcast terminals, personal digital assistants (PDAs), portable multimedia players (PMPs), navigators, portable computers (PCs), slate PCs, tablet PCs, ultra-books, wearable devices (for example, smart watches, smart glasses, head mounted displays (HMDs)), and the like.

By way of non-limiting example only, further description will be made with reference to particular types of mobile terminals. However, such teachings apply equally to other types of terminals, such as those types noted above. In addition, these teachings may also be applied to stationary terminals such as digital TV, desktop computers, and the like.

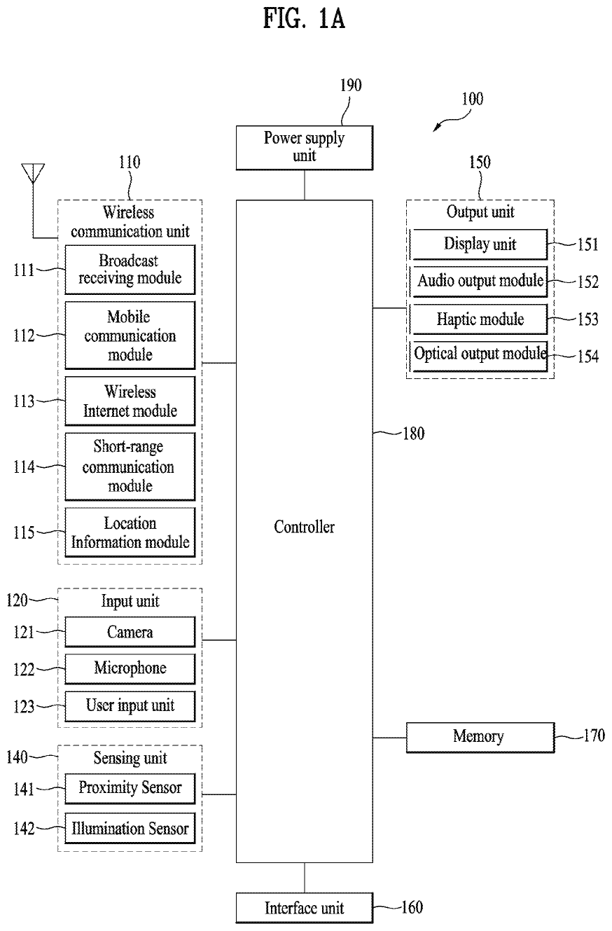

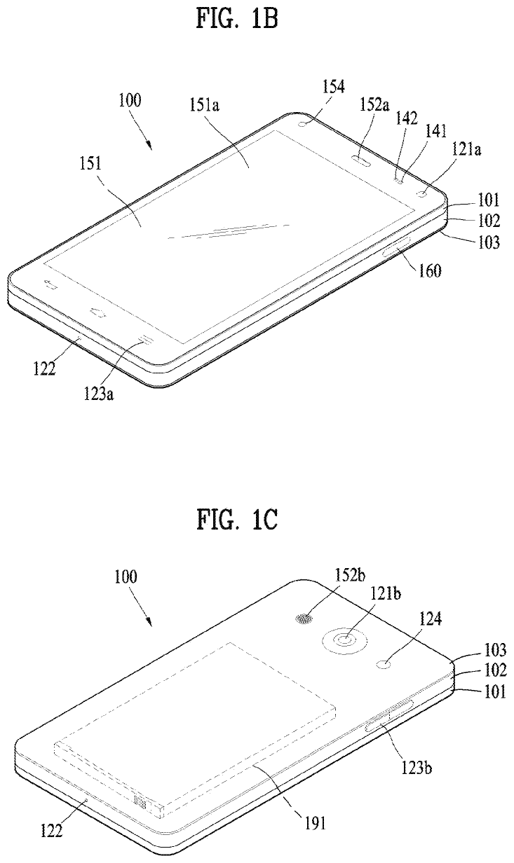

Reference is now made to FIGS. 1A-1C, where FIG. 1A is a block diagram of a mobile terminal in accordance with the present disclosure, and FIGS. 1B and 1C are conceptual views of one example of the mobile terminal, viewed from different directions.

The mobile terminal 100 is shown having components such as a wireless communication unit 110, an input unit 120, a sensing unit 140, an output unit 150, an interface unit 160, a memory 170, a controller 180, and a power supply unit 190. It is understood that implementing all of the illustrated components is not a requirement, and that greater or fewer components may alternatively be implemented.

For instance, the wireless communication unit 110 typically includes one or more components which permit wireless communication between the mobile terminal 100 and a wireless communication system or network within which the mobile terminal is located.

The wireless communication unit 110 includes one or more of a broadcast receiving module 111, a mobile communication module 112, a wireless Internet module 113, a short-range communication module 114, and a location information module 115.

The input unit 120 includes a camera 121 for obtaining images or video, a microphone 122, which is one type of audio input device for inputting an audio signal, and a user input unit 123 (for example, a touch key, a push key, a mechanical key, and the like) for allowing a user to input information. Data (for example, audio, image, and the like) is obtained by the input unit 120 and may be analyzed and processed by controller 180 according to user commands thereof.

The sensing unit 140 is typically implemented using one or more sensors configured to sense internal information of the mobile terminal, the surrounding environment of the mobile terminal, user information, and the like. For example, in FIG. 1A, the sensing unit 140 may include at least one of a proximity sensor 141, an illumination sensor 142, a touch sensor, an acceleration sensor, a magnetic sensor, a G-sensor, a gyroscope sensor, a motion sensor, an RGB sensor, an infrared (IR) sensor, a finger scan sensor, a ultrasonic sensor, an optical sensor (for example, camera 121), a microphone 122, a battery gauge, an environment sensor (for example, a barometer, a hygrometer, a thermometer, a radiation detection sensor, a thermal sensor, and a gas sensor, among others), and a chemical sensor (for example, an electronic nose, a health care sensor, a biometric sensor, and the like), to name a few. The mobile terminal 100 may be configured to utilize information obtained from sensing unit 140, and in particular, information obtained from one or more sensors of the sensing unit 140, and combinations thereof.

The output unit 150 is typically configured to output various types of information, such as audio, video, tactile output, and the like. The output unit 150 is shown having a display unit 151, an audio output module 152, a haptic module 153, and an optical output module 154. The display unit 151 may have an inter-layered structure or an integrated structure with a touch sensor in order to facilitate a touch screen. The touch screen may provide an output interface between the mobile terminal 100 and a user, as well as function as the user input unit 123 which provides an input interface between the mobile terminal 100 and the user.

The interface unit 160 serves as an interface with various types of external devices that can be coupled to the mobile terminal 100. The interface unit 160, for example, may include any of wired or wireless ports, external power supply ports, wired or wireless data ports, memory card ports, ports for connecting a device having an identification module, audio input/output (I/O) ports, video I/O ports, earphone ports, and the like. In some cases, the mobile terminal 100 may perform assorted control functions associated with a connected external device, in response to the external device being connected to the interface unit 160.

The memory 170 is typically implemented to store data to support various functions or features of the mobile terminal 100. For instance, the memory 170 may be configured to store application programs executed in the mobile terminal 100, data or instructions for operations of the mobile terminal 100, and the like. Some of these application programs may be downloaded from an external server via wireless communication. Other application programs may be installed within the mobile terminal 100 at time of manufacturing or shipping, which is typically the case for basic functions of the mobile terminal 100 (for example, receiving a call, placing a call, receiving a message, sending a message, and the like). It is common for application programs to be stored in the memory 170, installed in the mobile terminal 100, and executed by the controller 180 to perform an operation (or function) for the mobile terminal 100.

The controller 180 typically functions to control overall operation of the mobile terminal 100, in addition to the operations associated with the application programs. The controller 180 may provide or process information or functions appropriate for a user by processing signals, data, information and the like, which are input or output by the various components depicted in FIG. 1A, or activating application programs stored in the memory 170.

Moreover, the controller 180 controls some or all of the components illustrated in FIG. 1A according to the execution of an application program that have been stored in the memory 170.

The power supply unit 190 can be configured to receive external power or provide internal power in order to supply appropriate power required for operating elements and components included in the mobile terminal 100. The power supply unit 190 may include a battery, and the battery may be configured to be embedded in the terminal body, or configured to be detachable from the terminal body.

At least some of the above components can cooperatively operate to implement operations, controls and controlling methods of the mobile terminal according to various embodiments described in the following. The operations, controls or controlling methods of the mobile terminal can be implemented on the mobile terminal by running at least one application program saved to the memory 170.

Referring still to FIG. 1A, various components depicted in this figure will now be described in more detail.

Regarding the wireless communication unit 110, the broadcast receiving module 111 is typically configured to receive a broadcast signal and/or broadcast associated information from an external broadcast managing entity via a broadcast channel. The broadcast channel may include a satellite channel, a terrestrial channel, or both. In some embodiments, two or more broadcast receiving modules 111 may be utilized to facilitate simultaneously receiving of two or more broadcast channels, or to support switching among broadcast channels.

The broadcast managing server generally refers to a server which generates and transmits a broadcast signal and/or broadcast associated information or a server which is provided with a previously generated broadcast signal and/or broadcast associated information and then transmits the provided signal or information to a terminal. The broadcast signal may be implemented as a TV broadcast signal, a radio broadcast signal, and a data broadcast signal, among others. If desired, the broadcast signal may further include a broadcast signal combined with a TV or radio broadcast signal.

The broadcast signal may be encoded according to any of a variety of technical standards or broadcasting methods (for example, International Organization for Standardization (ISO), International Electro technical Commission (IEC), Digital Video Broadcast (DVB), Advanced Television Systems Committee (ATSC), and the like) for transmission and reception of digital broadcast signals. The broadcast receiving module 111 can receive the digital broadcast signals using a method appropriate for the transmission method utilized.

Examples of broadcast associated information may include information associated with a broadcast channel, a broadcast program, a broadcast event, a broadcast service provider, or the like. The broadcast associated information may also be provided via a mobile communication network, and in this case, received by the mobile communication module 112.

The broadcast associated information may be implemented in various formats. For instance, broadcast associated information may include an Electronic Program Guide (EPG) of Digital Multimedia Broadcasting (DMB), an Electronic Service Guide (ESG) of Digital Video Broadcast-Handheld (DVB-H), and the like. Broadcast signals and/or broadcast associated information received via the broadcast receiving module 111 may be stored in a suitable device, such as a memory 170.

The mobile communication module 112 can transmit and/or receive wireless signals to and from one or more network entities. Typical examples of a network entity include a base station, an external mobile terminal, a server, and the like. Such network entities form part of a mobile communication network, which is constructed according to technical standards or communication methods for mobile communications (for example, Global System for Mobile Communication (GSM), Code Division Multi Access (CDMA), CDMA2000 (Code Division Multi Access 2000), EV-DO (Enhanced Voice-Data Optimized or Enhanced Voice-Data Only), Wideband CDMA (WCDMA), High Speed Downlink Packet access (HSDPA), HSUPA (High Speed Uplink Packet Access), Long Term Evolution (LTE), LTE-A (Long Term Evolution-Advanced), and the like).

Examples of wireless signals transmitted and/or received via the mobile communication module 112 include audio call signals, video (telephony) call signals, or various formats of data to support communication of text and multimedia messages.

The wireless Internet module 113 is configured to facilitate wireless Internet access. This module may be internally or externally coupled to the mobile terminal 100. The wireless Internet module 113 may transmit and/or receive wireless signals via communication networks according to wireless Internet technologies.

Examples of such wireless Internet access include Wireless LAN (WLAN), Wireless Fidelity (Wi-Fi), Wi-Fi Direct, Digital Living Network Alliance (DLNA), Wireless Broadband (WiBro), Worldwide Interoperability for Microwave Access (WiMAX), High Speed Downlink Packet Access (HSDPA), HSUPA (High Speed Uplink Packet Access), Long Term Evolution (LTE), LTE-A (Long Term Evolution-Advanced), and the like. The wireless Internet module 113 may transmit/receive data according to one or more of such wireless Internet technologies, and other Internet technologies as well.

In some embodiments, when the wireless Internet access is implemented according to, for example, WiBro, HSDPA, HSUPA, GSM, CDMA, WCDMA, LTE, LTE-A and the like, as part of a mobile communication network, the wireless Internet module 113 performs such wireless Internet access. As such, the Internet module 113 may cooperate with, or function as, the mobile communication module 112.

The short-range communication module 114 is configured to facilitate short-range communications. Suitable technologies for implementing such short-range communications include BLUETOOTH™, Radio Frequency IDentification (RFID), Infrared Data Association (IrDA), Ultra-WideBand (UWB), ZigBee, Near Field Communication (NFC), Wireless-Fidelity (Wi-Fi) and Wi-Fi Direct, and the like. The short-range communication module 114 in general supports wireless communications between the mobile terminal 100 and a wireless communication system, communications between the mobile terminal 100 and another mobile terminal 100, or communications between the mobile terminal and a network where another mobile terminal 100 (or an external server) is located, via wireless area networks. One example of the wireless area networks is a wireless personal area networks.

In some embodiments, another mobile terminal (which may be configured similarly to mobile terminal 100) may be a wearable device, for example, a smart watch, a smart glass or a head mounted display (HMD), which is able to exchange data with the mobile terminal 100 (or otherwise cooperate with the mobile terminal 100). The short-range communication module 114 may sense or recognize the wearable device, and permit communication between the wearable device and the mobile terminal 100. In addition, when the sensed wearable device is a device which is authenticated to communicate with the mobile terminal 100, the controller 180, for example, may cause transmission of data processed in the mobile terminal 100 to the wearable device via the short-range communication module 114. Hence, a user of the wearable device may use the data processed in the mobile terminal 100 on the wearable device. For example, when a call is received in the mobile terminal 100, the user may answer the call using the wearable device. Also, when a message is received in the mobile terminal 100, the user can check the received message using the wearable device.

The location information module 115 is generally configured to detect, calculate, derive or otherwise identify a position of the mobile terminal. As an example, the location information module 115 includes a Global Position System (GPS) module, a Wi-Fi module, or both. As one example, when the mobile terminal uses a GPS module, a position of the mobile terminal may be acquired using a signal sent from a GPS satellite. As another example, when the mobile terminal uses the Wi-Fi module, a position of the mobile terminal can be acquired based on information related to a wireless access point (AP) which transmits or receives a wireless signal to or from the Wi-Fi module.

The input unit 120 may be configured to permit various types of input to the mobile terminal 120. Examples of such input include audio, image, video, data, and user input. Image and video input is often obtained using one or more cameras 121. Such cameras 121 may process image frames of still pictures or video obtained by image sensors in a video or image capture mode. The processed image frames can be displayed on the display unit 151 or stored in memory 170. In some cases, the cameras 121 may be arranged in a matrix configuration to permit a plurality of images having various angles or focal points to be input to the mobile terminal 100. As another example, the cameras 121 may be located in a stereoscopic arrangement to acquire left and right images for implementing a stereoscopic image.

The microphone 122 is generally implemented to permit audio input to the mobile terminal 100. The audio input can be processed in various manners according to a function being executed in the mobile terminal 100. If desired, the microphone 122 may include assorted noise removing algorithms to remove unwanted noise generated in the course of receiving the external audio.

The user input unit 123 is a component that permits input by a user. Such user input may enable the controller 180 to control operation of the mobile terminal 100. The user input unit 123 may include one or more of a mechanical input element (for example, a key, a button located on a front and/or rear surface or a side surface of the mobile terminal 100, a dome switch, a jog wheel, a jog switch, and the like), or a touch-sensitive input, among others. As one example, the touch-sensitive input may be a virtual key or a soft key, which is displayed on a touch screen through software processing, or a touch key which is located on the mobile terminal at a location that is other than the touch screen. On the other hand, the virtual key or the visual key may be displayed on the touch screen in various shapes, for example, graphic, text, icon, video, or a combination thereof.

The sensing unit 140 is generally configured to sense one or more of internal information of the mobile terminal, surrounding environment information of the mobile terminal, user information, or the like. The controller 180 generally cooperates with the sending unit 140 to control operation of the mobile terminal 100 or execute data processing, a function or an operation associated with an application program installed in the mobile terminal based on the sensing provided by the sensing unit 140. The sensing unit 140 may be implemented using any of a variety of sensors, some of which will now be described in more detail.

The proximity sensor 141 may include a sensor to sense presence or absence of an object approaching a surface, or an object located near a surface, by using an electromagnetic field, infrared rays, or the like without a mechanical contact. The proximity sensor 141 may be arranged at an inner region of the mobile terminal covered by the touch screen, or near the touch screen.

The proximity sensor 141, for example, may include any of a transmissive type photoelectric sensor, a direct reflective type photoelectric sensor, a mirror reflective type photoelectric sensor, a high-frequency oscillation proximity sensor, a capacitance type proximity sensor, a magnetic type proximity sensor, an infrared rays proximity sensor, and the like. When the touch screen is implemented as a capacitance type, the proximity sensor 141 can sense proximity of a pointer relative to the touch screen by changes of an electromagnetic field, which is responsive to an approach of an object with conductivity. In this case, the touch screen (touch sensor) may also be categorized as a proximity sensor.

The term “proximity touch” will often be referred to herein to denote the scenario in which a pointer is positioned to be proximate to the touch screen without contacting the touch screen. The term “contact touch” will often be referred to herein to denote the scenario in which a pointer makes physical contact with the touch screen. For the position corresponding to the proximity touch of the pointer relative to the touch screen, such position will correspond to a position where the pointer is perpendicular to the touch screen. The proximity sensor 141 may sense proximity touch, and proximity touch patterns (for example, distance, direction, speed, time, position, moving status, and the like). In general, controller 180 processes data corresponding to proximity touches and proximity touch patterns sensed by the proximity sensor 141, and cause output of visual information on the touch screen. In addition, the controller 180 can control the mobile terminal 100 to execute different operations or process different data according to whether a touch with respect to a point on the touch screen is either a proximity touch or a contact touch.

A touch sensor can sense a touch applied to the touch screen, such as display unit 151, using any of a variety of touch methods. Examples of such touch methods include a resistive type, a capacitive type, an infrared type, and a magnetic field type, among others.

As one example, the touch sensor may be configured to convert changes of pressure applied to a specific part of the display unit 151, or convert capacitance occurring at a specific part of the display unit 151, into electric input signals. The touch sensor may also be configured to sense not only a touched position and a touched region, but also touch pressure and/or touch capacitance. A touch object is generally used to apply a touch input to the touch sensor. Examples of typical touch objects include a finger, a touch pen, a stylus pen, a pointer, or the like.

When a touch input is sensed by a touch sensor, corresponding signals may be transmitted to a touch controller. The touch controller may process the received signals, and then transmit corresponding data to the controller 180. Accordingly, the controller 180 may sense which region of the display unit 151 has been touched. Here, the touch controller may be a component separate from the controller 180, the controller 180, and combinations thereof.

In some embodiments, the controller 180 may execute the same or different controls according to a type of touch object that touches the touch screen or a touch key provided in addition to the touch screen. Whether to execute the same or different control according to the object which provides a touch input may be decided based on a current operating state of the mobile terminal 100 or a currently executed application program, for example.

The touch sensor and the proximity sensor may be implemented individually, or in combination, to sense various types of touches. Such touches includes a short (or tap) touch, a long touch, a multi-touch, a drag touch, a flick touch, a pinch-in touch, a pinch-out touch, a swipe touch, a hovering touch, and the like.

If desired, an ultrasonic sensor may be implemented to recognize position information relating to a touch object using ultrasonic waves. The controller 180, for example, may calculate a position of a wave generation source based on information sensed by an illumination sensor and a plurality of ultrasonic sensors. Since light is much faster than ultrasonic waves, the time for which the light reaches the optical sensor is much shorter than the time for which the ultrasonic wave reaches the ultrasonic sensor. The position of the wave generation source may be calculated using this fact. For instance, the position of the wave generation source may be calculated using the time difference from the time that the ultrasonic wave reaches the sensor based on the light as a reference signal.

The camera 121 typically includes at least one a camera sensor (CCD, CMOS etc.), a photo sensor (or image sensors), and a laser sensor.

Implementing the camera 121 with a laser sensor may allow detection of a touch of a physical object with respect to a 3D stereoscopic image. The photo sensor may be laminated on, or overlapped with, the display device. The photo sensor may be configured to scan movement of the physical object in proximity to the touch screen. In more detail, the photo sensor may include photo diodes and transistors at rows and columns to scan content received at the photo sensor using an electrical signal which changes according to the quantity of applied light. Namely, the photo sensor may calculate the coordinates of the physical object according to variation of light to thus obtain position information of the physical object.

The display unit 151 is generally configured to output information processed in the mobile terminal 100. For example, the display unit 151 may display execution screen information of an application program executing at the mobile terminal 100 or user interface (UI) and graphic user interface (GUI) information in response to the execution screen information.

In some embodiments, the display unit 151 may be implemented as a stereoscopic display unit for displaying stereoscopic images.

A typical stereoscopic display unit may employ a stereoscopic display scheme such as a stereoscopic scheme (a glass scheme), an auto-stereoscopic scheme (glassless scheme), a projection scheme (holographic scheme), or the like.

In general, a 3D stereoscopic image may include a left image (e.g., a left eye image) and a right image (e.g., a right eye image). According to how left and right images are combined into a 3D stereoscopic image, a 3D stereoscopic imaging method can be divided into a top-down method in which left and right images are located up and down in a frame, an L-to-R (left-to-right or side by side) method in which left and right images are located left and right in a frame, a checker board method in which fragments of left and right images are located in a tile form, an interlaced method in which left and right images are alternately located by columns or rows, and a time sequential (or frame by frame) method in which left and right images are alternately displayed on a time basis.

Also, as for a 3D thumbnail image, a left image thumbnail and a right image thumbnail can be generated from a left image and a right image of an original image frame, respectively, and then combined to generate a single 3D thumbnail image. In general, the term “thumbnail” may be used to refer to a reduced image or a reduced still image. A generated left image thumbnail and right image thumbnail may be displayed with a horizontal distance difference there between by a depth corresponding to the disparity between the left image and the right image on the screen, thereby providing a stereoscopic space sense.

A left image and a right image required for implementing a 3D stereoscopic image may be displayed on the stereoscopic display unit using a stereoscopic processing unit. The stereoscopic processing unit can receive the 3D image and extract the left image and the right image, or can receive the 2D image and change it into a left image and a right image.

The audio output module 152 is generally configured to output audio data. Such audio data may be obtained from any of a number of different sources, such that the audio data may be received from the wireless communication unit 110 or may have been stored in the memory 170. The audio data may be output during modes such as a signal reception mode, a call mode, a record mode, a voice recognition mode, a broadcast reception mode, and the like. The audio output module 152 can provide audible output related to a particular function (e.g., a call signal reception sound, a message reception sound, etc.) performed by the mobile terminal 100. The audio output module 152 may also be implemented as a receiver, a speaker, a buzzer, or the like.

A haptic module 153 can be configured to generate various tactile effects that a user feels, perceive, or otherwise experience. A typical example of a tactile effect generated by the haptic module 153 is vibration. The strength, pattern and the like of the vibration generated by the haptic module 153 can be controlled by user selection or setting by the controller. For example, the haptic module 153 may output different vibrations in a combining manner or a sequential manner.

Besides vibration, the haptic module 153 can generate various other tactile effects, including an effect by stimulation such as a pin arrangement vertically moving to contact skin, a spray force or suction force of air through a jet orifice or a suction opening, a touch to the skin, a contact of an electrode, electrostatic force, an effect by reproducing the sense of cold and warmth using an element that can absorb or generate heat, and the like.

The haptic module 153 can also be implemented to allow the user to feel a tactile effect through a muscle sensation such as the user's fingers or arm, as well as transferring the tactile effect through direct contact. Two or more haptic modules 153 may be provided according to the particular configuration of the mobile terminal 100.

An optical output module 154 can output a signal for indicating an event generation using light of a light source. Examples of events generated in the mobile terminal 100 may include message reception, call signal reception, a missed call, an alarm, a schedule notice, an email reception, information reception through an application, and the like.

A signal output by the optical output module 154 may be implemented in such a manner that the mobile terminal emits monochromatic light or light with a plurality of colors. The signal output may be terminated as the mobile terminal senses that a user has checked the generated event, for example.

The interface unit 160 serves as an interface for external devices to be connected with the mobile terminal 100. For example, the interface unit 160 can receive data transmitted from an external device, receive power to transfer to elements and components within the mobile terminal 100, or transmit internal data of the mobile terminal 100 to such external device. The interface unit 160 may include wired or wireless headset ports, external power supply ports, wired or wireless data ports, memory card ports, ports for connecting a device having an identification module, audio input/output (I/O) ports, video I/O ports, earphone ports, or the like.

The identification module may be a chip that stores various information for authenticating authority of using the mobile terminal 100 and may include a user identity module (UIM), a subscriber identity module (SIM), a universal subscriber identity module (USIM), and the like. In addition, the device having the identification module (also referred to herein as an “identifying device”) may take the form of a smart card. Accordingly, the identifying device can be connected with the terminal 100 via the interface unit 160.

When the mobile terminal 100 is connected with an external cradle, the interface unit 160 can serve as a passage to allow power from the cradle to be supplied to the mobile terminal 100 or may serve as a passage to allow various command signals input by the user from the cradle to be transferred to the mobile terminal there through. Various command signals or power input from the cradle may operate as signals for recognizing that the mobile terminal is properly mounted on the cradle.

The memory 170 can store programs to support operations of the controller 180 and store input/output data (for example, phonebook, messages, still images, videos, etc.). The memory 170 may store data related to various patterns of vibrations and audio which are output in response to touch inputs on the touch screen.

The memory 170 may include one or more types of storage mediums including a Flash memory, a hard disk, a solid state disk, a silicon disk, a multimedia card micro type, a card-type memory (e.g., SD or DX memory, etc.), a Random Access Memory (RAM), a Static Random Access Memory (SRAM), a Read-Only Memory (ROM), an Electrically Erasable Programmable Read-Only Memory (EEPROM), a Programmable Read-Only memory (PROM), a magnetic memory, a magnetic disk, an optical disk, and the like. The mobile terminal 100 may also be operated in relation to a network storage device that performs the storage function of the memory 170 over a network, such as the Internet.

The controller 180 may typically control the general operations of the mobile terminal 100. For example, the controller 180 may set or release a lock state for restricting a user from inputting a control command with respect to applications when a status of the mobile terminal meets a preset condition.

The controller 180 can also perform the controlling and processing associated with voice calls, data communications, video calls, and the like, or perform pattern recognition processing to recognize a handwriting input or a picture drawing input performed on the touch screen as characters or images, respectively. In addition, the controller 180 can control one or a combination of those components in order to implement various exemplary embodiments disclosed herein.

The power supply unit 190 receives external power or provides internal power and supply the appropriate power required for operating respective elements and components included in the mobile terminal 100. The power supply unit 190 may include a battery, which is typically rechargeable or be detachably coupled to the terminal body for charging.

The power supply unit 190 may include a connection port. The connection port may be configured as one example of the interface unit 160 to which an external charger for supplying power to recharge the battery is electrically connected.

As another example, the power supply unit 190 may be configured to recharge the battery in a wireless manner without use of the connection port. In this example, the power supply unit 190 can receive power, transferred from an external wireless power transmitter, using at least one of an inductive coupling method which is based on magnetic induction or a magnetic resonance coupling method which is based on electromagnetic resonance.

Various embodiments described herein may be implemented in a computer-readable medium, a machine-readable medium, or similar medium using, for example, software, hardware, or any combination thereof.

Referring now to FIGS. 1B and 1C, the mobile terminal 100 is described with reference to a bar-type terminal body. However, the mobile terminal 100 may alternatively be implemented in any of a variety of different configurations. Examples of such configurations include watch-type, clip-type, glasses-type, or as a folder-type, flip-type, slide-type, swing-type, and swivel-type in which two and more bodies are combined with each other in a relatively movable manner, and combinations thereof.

In this case, the terminal body can be construed as the concept of indicating the mobile terminal 100 as at least one assembly.

The mobile terminal 100 will generally include a case (for example, frame, housing, cover, and the like) forming the appearance of the terminal. In this embodiment, the case is formed using a front case 101 and a rear case 102. Various electronic components are incorporated into a space formed between the front case 101 and the rear case 102. At least one middle case may be additionally positioned between the front case 101 and the rear case 102.

The display unit 151 is shown located on the front side of the terminal body to output information. As illustrated, a window 151a of the display unit 151 may be mounted to the front case 101 to form the front surface of the terminal body together with the front case 101.

In some embodiments, electronic components may also be mounted to the rear case 102. Examples of such electronic components include a detachable battery 191, an identification module, a memory card, and the like. Rear cover 103 is shown covering the electronic components, and this cover may be detachably coupled to the rear case 102. Therefore, when the rear cover 103 is detached from the rear case 102, the electronic components mounted to the rear case 102 are externally exposed.

As illustrated, when the rear cover 103 is coupled to the rear case 102, a side surface of the rear case 102 is partially exposed. In some cases, upon the coupling, the rear case 102 may also be completely shielded by the rear cover 103. In some embodiments, the rear cover 103 may include an opening for externally exposing a camera 121b or an audio output module 152b.

The cases 101, 102, 103 may be formed by injection-molding synthetic resin or may be formed of a metal, for example, stainless steel (STS), aluminum (Al), titanium (Ti), or the like.

As an alternative to the example in which the plurality of cases form an inner space for accommodating components, the mobile terminal 100 may be configured such that one case forms the inner space. In this example, a mobile terminal 100 having a uni-body is formed in such a manner that synthetic resin or metal extends from a side surface to a rear surface.

If desired, the mobile terminal 100 may include a waterproofing unit (not shown) for preventing introduction of water into the terminal body. For example, the waterproofing unit may include a waterproofing member which is located between the window 151a and the front case 101, between the front case 101 and the rear case 102, or between the rear case 102 and the rear cover 103, to hermetically seal an inner space when those cases are coupled.

The mobile terminal includes a display unit 151, a first and a second audio output modules 151a/151b, a proximity sensor 141, an illumination sensor 142, an optical output module 154, a first and a second cameras 121a/121b, a first and a second manipulation units 123a/123b, a microphone 122, interface unit 160 and the like.

It will be described for the mobile terminal as shown in FIGS. 1B and 1C. The display unit 151, the first audio output module 151a, the proximity sensor 141, an illumination sensor 142, the optical output module 154, the first camera 121a and the first manipulation unit 123a are arranged in front surface of the terminal body, the second manipulation unit 123b, the microphone 122 and interface unit 160 are arranged in side surface of the terminal body, and the second audio output modules 151b and the second camera 121b are arranged in rear surface of the terminal body.

However, it is to be understood that alternative arrangements are possible and within the teachings of the instant disclosure. Some components may be omitted or rearranged. For example, the first manipulation unit 123a may be located on another surface of the terminal body, and the second audio output module 152b may be located on the side surface of the terminal body.

The display unit 151 outputs information processed in the mobile terminal 100. For example, the display unit 151 may display an execution screen information of an application operated in the mobile terminal or User Interface, Graphic User Interface corresponding to the execution screen information.

The display unit 151 may be implemented using one or more suitable display devices. Examples of such suitable display devices include a liquid crystal display (LCD), a thin film transistor-liquid crystal display (TFT-LCD), an organic light emitting diode (OLED), a flexible display, a 3-dimensional (3D) display, an e-ink display, and combinations thereof.

Moreover, the display unit 151 may be implemented using two display devices, which can implement the same or different display technology. For instance, a plurality of the display units 151 may be arranged on one side, either spaced apart from each other, or these devices may be integrated, or these devices may be arranged on different surfaces.

The display unit 151 may also include a touch sensor which senses a touch input received at the display unit. When a touch is input to the display unit 151, the touch sensor may be configured to sense this touch and the controller 180, for example, may generate a control command or other signal corresponding to the touch. The content which is input in the touching manner may be a text or numerical value, or a menu item which can be indicated or designated in various modes.

The touch sensor may be configured in a form of a film having a touch pattern, disposed between the window 151a and a display on a rear surface of the window 151a, or a metal wire which is patterned directly on the rear surface of the window 151a. Alternatively, the touch sensor may be integrally formed with the display. For example, the touch sensor may be disposed on a substrate of the display or within the display.

The display unit 151 may also form a touch screen together with the touch sensor. Here, the touch screen may serve as the user input unit 123 (see FIG. 1A). Therefore, the touch screen may replace at least some of the functions of the first manipulation unit 123a.

The first audio output module 152a may be implemented in the form of a speaker to output voice audio, alarm sounds, multimedia audio reproduction, and the like.

The window 151a of the display unit 151 will typically include an aperture to permit audio generated by the first audio output module 152a to pass. One alternative is to allow audio to be released along an assembly gap between the structural bodies (for example, a gap between the window 151a and the front case 101). In this case, a hole independently formed to output audio sounds may not be seen or is otherwise hidden in terms of appearance, thereby further simplifying the appearance and manufacturing of the mobile terminal 100.

The optical output module 154 can be configured to output light for indicating an event generation. Examples of such events include a message reception, a call signal reception, a missed call, an alarm, a schedule notice, an email reception, information reception through an application, and the like. When a user has checked a generated event, the controller can control the optical output unit 154 to stop the light output.

The first camera 121a can process image frames such as still or moving images obtained by the image sensor in a capture mode or a video call mode. The processed image frames can then be displayed on the display unit 151 or stored in the memory 170.

The first and second manipulation units 123a and 123b are examples of the user input unit 123, which may be manipulated by a user to provide input to the mobile terminal 100. The first and second manipulation units 123a and 123b may also be commonly referred to as a manipulating portion, and may employ any tactile method that allows the user to perform manipulation such as touch, push, scroll, or the like.

In the present drawing, the first manipulation unit 123a is a touch key for example, by which the present invention is non-limited. For instance, the first manipulation unit 123 may include a push key (i.e., a mechanical key) or a combination of the touch key and the push key.

Input received at the first and second manipulation units 123a and 123b may be used in various ways. For example, the first manipulation unit 123a may be used by the user to provide an input to a menu, home key, cancel, search, or the like, and the second manipulation unit 123b may be used by the user to provide an input to control a volume level being output from the first or second audio output modules 152a or 152b, to switch to a touch recognition mode of the display unit 151, or the like.

As another example of the user input unit 123, a rear input unit (not shown) may be located on the rear surface of the terminal body. The rear input unit can be manipulated by a user to provide input to the mobile terminal 100. The input may be used in a variety of different ways. For example, the rear input unit may be used by the user to provide an input for power on/off, start, end, scroll, control volume level being output from the first or second audio output modules 152a or 152b, switch to a touch recognition mode of the display unit 151, and the like. The rear input unit may be configured to permit touch input, a push input, or combinations thereof.

The rear input unit may be located to overlap the display unit 151 of the front side in a thickness direction of the terminal body. As one example, the rear input unit may be located on an upper end portion of the rear side of the terminal body such that a user can easily manipulate it using a forefinger when the user grabs the terminal body with one hand. Alternatively, the rear input unit can be positioned at most any location of the rear side of the terminal body.

Embodiments that include the rear input unit may implement some or all of the functionality of the first manipulation unit 123a in the rear input unit. As such, in situations where the first manipulation unit 123a is omitted from the front side, the display unit 151 can have a larger screen.

As a further alternative, the mobile terminal 100 may include a finger scan sensor which scans a user's fingerprint. The controller 180 can then use fingerprint information sensed by the finger scan sensor as part of an authentication procedure. The finger scan sensor may also be installed in the display unit 151 or implemented in the user input unit 123.

The microphone 122 is shown located at an end of the mobile terminal 100, but other locations are possible. If desired, multiple microphones may be implemented, with such an arrangement permitting the receiving of stereo sounds.

The interface unit 160 may serve as a path allowing the mobile terminal 100 to interface with external devices. For example, the interface unit 160 may include one or more of a connection terminal for connecting to another device (for example, an earphone, an external speaker, or the like), a port for near field communication (for example, an Infrared Data Association (IrDA) port, a Bluetooth port, a wireless LAN port, and the like), or a power supply terminal for supplying power to the mobile terminal 100. The interface unit 160 may be implemented in the form of a socket for accommodating an external card, such as Subscriber Identification Module (SIM), User Identity Module (UIM), or a memory card for information storage.

The second camera 121b is shown located at the rear side of the terminal body and includes an image capturing direction that is substantially opposite to the image capturing direction of the first camera unit 121a. If desired, second camera 121a may alternatively be located at other locations, or made to be moveable, in order to have a different image capturing direction from that which is shown.

The second camera 121b can include a plurality of lenses arranged along at least one line. The plurality of lenses may also be arranged in a matrix configuration. The cameras may be referred to as an “array camera.” When the second camera 121b is implemented as an array camera, images may be captured in various manners using the plurality of lenses and images with better qualities.

A flash 124 is shown adjacent to the second camera 121b. When an image of a subject is captured with the camera 121b, the flash 124 may illuminate the subject.

The second audio output module 152b can be located on the terminal body. The second audio output module 152b may implement stereophonic sound functions in conjunction with the first audio output module 152a, and may be also used for implementing a speaker phone mode for call communication.

At least one antenna for wireless communication may be located on the terminal body. The antenna may be installed in the terminal body or formed by the case. For example, an antenna which configures a part of the broadcast receiving module 111 may be retractable into the terminal body. Alternatively, an antenna may be formed using a film attached to an inner surface of the rear cover 103, or a case that includes a conductive material.

A power supply unit 190 for supplying power to the mobile terminal 100 may include a battery 191, which is mounted in the terminal body or detachably coupled to an outside of the terminal body. The battery 191 may receive power via a power source cable connected to the interface unit 160.

The battery 191 can be recharged in a wireless manner using a wireless charger. Wireless charging may be implemented by magnetic induction or electromagnetic resonance.

The rear cover 103 is shown coupled to the rear case 102 for shielding the battery 191, to prevent separation of the battery 191, and to protect the battery 191 from an external impact or from foreign material. When the battery 191 is detachable from the terminal body, the rear case 103 may be detachably coupled to the rear case 102.

An accessory for protecting an appearance or assisting or extending the functions of the mobile terminal 100 can also be provided on the mobile terminal 100. As one example of an accessory, a cover or pouch for covering or accommodating at least one surface of the mobile terminal 100 may be provided. The cover or pouch may cooperate with the display unit 151 to extend the function of the mobile terminal 100. Another example of the accessory is a touch pen for assisting or extending a touch input to a touch screen.

Meanwhile, according to the present invention, information processed by a mobile terminal can be displayed using a flexible display. Regarding this, it shall be described in more detail with reference to the attached drawing in the following.

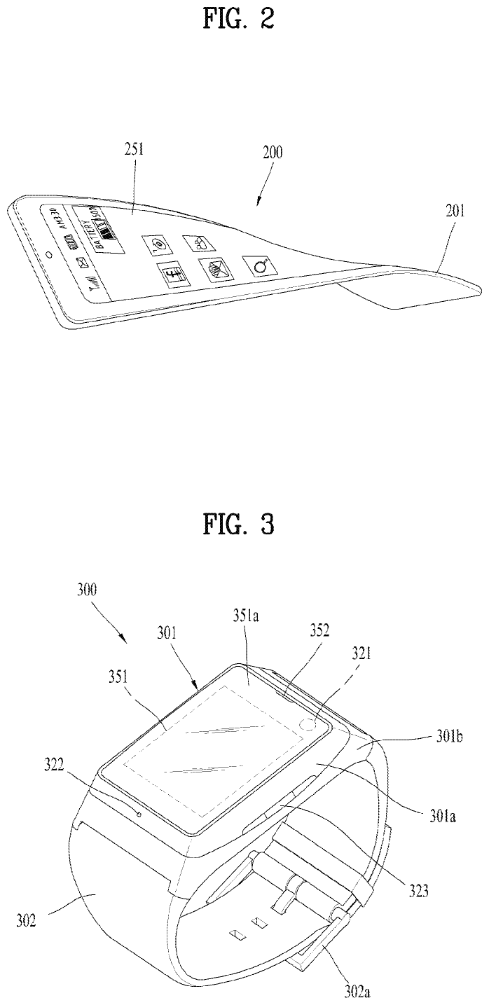

FIG. 2 is a perspective view illustrating one example of a watch-type mobile terminal 300 in accordance with another exemplary embodiment.

In this figure, mobile terminal 200 is shown having display unit 251, which is a type of display that is deformable by an external force. This deformation, which includes display unit 251 and other components of mobile terminal 200, may include any of curving, bending, folding, twisting, rolling, and combinations thereof. The deformable display unit 251 may also be referred to as a “flexible display unit.” In some implementations, the flexible display unit 251 may include a general flexible display, electronic paper (also known as e-paper), and combinations thereof. In general, mobile terminal 200 may be configured to include features that are the same or similar to that of mobile terminal 100 of FIGS. 1A-1C.

The flexible display of mobile terminal 200 is generally formed as a lightweight, non-fragile display, which still exhibits characteristics of a conventional flat panel display, but is instead fabricated on a flexible substrate which can be deformed as noted previously.

The term e-paper may be used to refer to a display technology employing the characteristic of a general ink, and is different from the conventional flat panel display in view of using reflected light. E-paper is generally understood as changing displayed information using a twist ball or via electrophoresis using a capsule.

When in a state that the flexible display unit 251 is not deformed (for example, in a state with an infinite radius of curvature and referred to as a first state), a display region of the flexible display unit 251 includes a generally flat surface. When in a state that the flexible display unit 251 is deformed from the first state by an external force (for example, a state with a finite radius of curvature and referred to as a second state), the display region may become a curved surface or a bent surface. As illustrated, information displayed in the second state may be visual information output on the curved surface. The visual information may be realized in such a manner that a light emission of each unit pixel (sub-pixel) arranged in a matrix configuration is controlled independently. The unit pixel denotes an elementary unit for representing one color.

According to one alternative embodiment, the first state of the flexible display unit 251 may be a curved state (for example, a state of being curved from up to down or from right to left), instead of being in flat state. In this embodiment, when an external force is applied to the flexible display unit 251, the flexible display unit 251 may transition to the second state such that the flexible display unit is deformed into the flat state (or a less curved state) or into a more curved state.

If desired, the flexible display unit 251 may implement a flexible touch screen using a touch sensor in combination with the display. When a touch is received at the flexible touch screen, the controller 180 can execute certain control corresponding to the touch input. In general, the flexible touch screen is configured to sense touch and other input while in both the first and second states.

One option is to configure the mobile terminal 200 to include a deformation sensor which senses the deforming of the flexible display unit 251. The deformation sensor may be included in the sensing unit 140.

The deformation sensor may be located in the flexible display unit 251 or the case 201 to sense information related to the deforming of the flexible display unit 251. Examples of such information related to the deforming of the flexible display unit 251 may be a deformed direction, a deformed degree, a deformed position, a deformed amount of time, an acceleration that the deformed flexible display unit 251 is restored, and the like. Other possibilities include most any type of information which can be sensed in response to the curving of the flexible display unit or sensed while the flexible display unit 251 is transitioning into, or existing in, the first and second states.

In some embodiments, controller 180 or other component can change information displayed on the flexible display unit 251, or generate a control signal for controlling a function of the mobile terminal 200, based on the information related to the deforming of the flexible display unit 251. Such information is typically sensed by the deformation sensor.

The mobile terminal 200 is shown having a case 201 for accommodating the flexible display unit 251. The case 201 can be deformable together with the flexible display unit 251, taking into account the characteristics of the flexible display unit 251.

A battery (not shown in this figure) located in the mobile terminal 200 may also be deformable in cooperation with the flexible display unit 261, taking into account the characteristic of the flexible display unit 251. One technique to implement such a battery is to use a stack and folding method of stacking battery cells.

The deformation of the flexible display unit 251 not limited to perform by an external force. For example, the flexible display unit 251 can be deformed into the second state from the first state by a user command, application command, or the like.

In accordance with still further embodiments, a mobile terminal may be configured as a device which is wearable on a human body. Such devices go beyond the usual technique of a user grasping the mobile terminal using their hand. Examples of the wearable device include a smart watch, a smart glass, a head mounted display (HMD), and the like.

A typical wearable device can exchange data with (or cooperate with) another mobile terminal 100. In such a device, the wearable device generally has functionality that is less than the cooperating mobile terminal. For instance, the short-range communication module 114 of a mobile terminal 100 may sense or recognize a wearable device that is near-enough to communicate with the mobile terminal. In addition, when the sensed wearable device is a device which is authenticated to communicate with the mobile terminal 100, the controller 180 may transmit data processed in the mobile terminal 100 to the wearable device via the short-range communication module 114, for example. Hence, a user of the wearable device can use the data processed in the mobile terminal 100 on the wearable device. For example, when a call is received in the mobile terminal 100, the user can answer the call using the wearable device. Also, when a message is received in the mobile terminal 100, the user can check the received message using the wearable device.

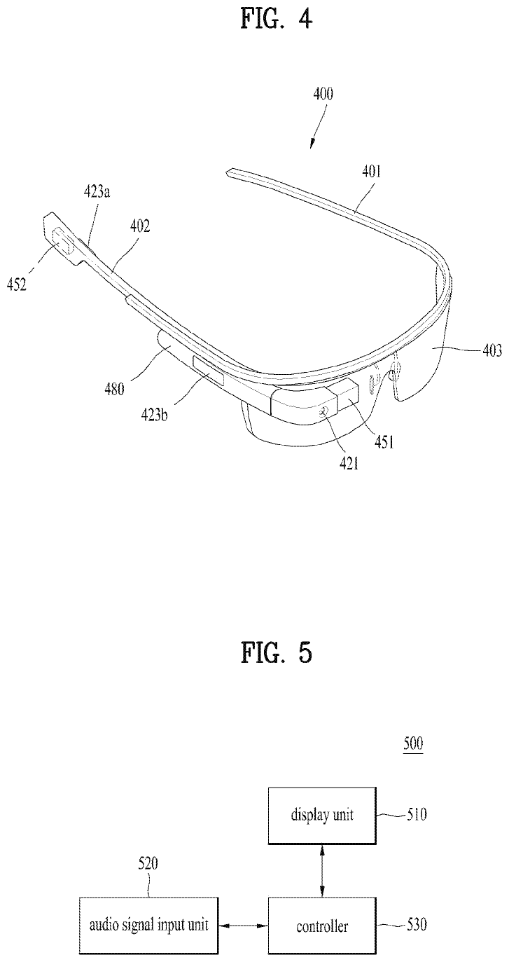

FIG. 3 is a perspective view illustrating one example of a watch-type mobile terminal 300 in accordance with another exemplary embodiment.

As illustrated in FIG. 3, the watch-type mobile terminal 300 includes a main body 301 with a display unit 351 and a band 302 connected to the main body 301 to be wearable on a wrist. In general, mobile terminal 300 may be configured to include features that are the same or similar to that of mobile terminal 100 of FIGS. 1A-1C.

The main body 301 may include a case having a certain appearance. As illustrated, the case may include a first case 301a and a second case 301b cooperatively defining an inner space for accommodating various electronic components. Other configurations are possible. For instance, a single case may alternatively be implemented, with such a case being configured to define the inner space, thereby implementing a mobile terminal 300 with a uni-body.

The watch-type mobile terminal 300 can perform wireless communication, and an antenna for the wireless communication can be installed in the main body 301. The antenna may extend its function using the case. For example, a case including a conductive material may be electrically connected to the antenna to extend a ground region or a radiation region.

The display unit 351 is shown located at the front side of the main body 301 so that displayed information is viewable to a user. In some embodiments, the display unit 351 includes a touch sensor so that the display unit can function as a touch screen. As illustrated, window 351a is positioned on the first case 301a to form a front surface of the terminal body together with the first case 301a.

The illustrated embodiment includes audio output module 352, a camera 321, a microphone 322, and a user input unit 323 positioned on the main body 301. When the display unit 351 is implemented as a touch screen, additional function keys may be minimized or eliminated. For example, when the touch screen is implemented, the user input unit 323 may be omitted.

The band 302 is commonly worn on the user's wrist and may be made of a flexible material for facilitating wearing of the device. As one example, the band 302 may be made of fur, rubber, silicon, synthetic resin, or the like. The band 302 may also be configured to be detachable from the main body 301. Accordingly, the band 302 may be replaceable with various types of bands according to a user's preference.

In one configuration, the band 302 may be used for extending the performance of the antenna. For example, the band may include therein a ground extending portion (not shown) electrically connected to the antenna to extend a ground region.

The band 302 may include fastener 302a. The fastener 302a may be implemented into a buckle type, a snap-fit hook structure, a Velcro® type, or the like, and include a flexible section or material. The drawing illustrates an example that the fastener 302a is implemented using a buckle.

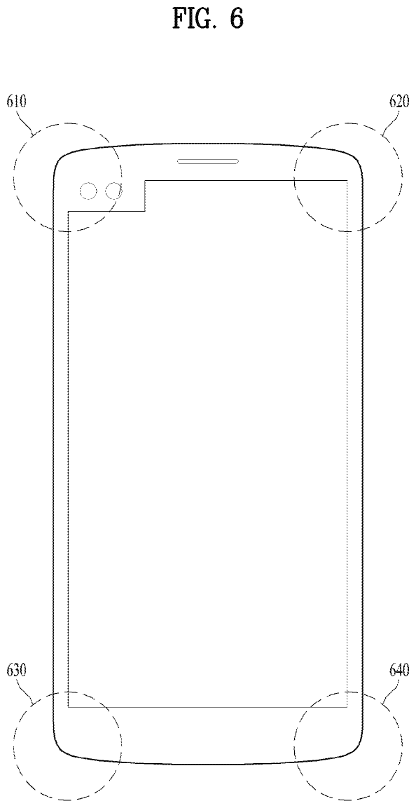

FIG. 4 is a perspective view illustrating one example of a glass-type mobile terminal 400 according to another exemplary embodiment.

The glass-type mobile terminal 400 can be wearable on a head of a human body and provided with a frame (case, housing, etc.) therefor. The frame may be made of a flexible material to be easily worn. The frame of mobile terminal 400 is shown having a first frame 401 and a second frame 402, which can be made of the same or different materials. In general, mobile terminal 400 may be configured to include features that are the same or similar to that of mobile terminal 100 of FIGS. 1A-1C.

The frame may be supported on the head and defines a space for mounting various components. As illustrated, electronic components, such as a control module 480, an audio output module 452, and the like, may be mounted to the frame part. Also, a lens 403 for covering either or both of the left and right eyes may be detachably coupled to the frame part.

The control module 480 controls various electronic components disposed in the mobile terminal 400. The control module 480 may be understood as a component corresponding to the aforementioned controller 180. FIG. 4 illustrates that the control module 480 is installed in the frame part on one side of the head, but other locations are possible.

The display unit 451 may be implemented as a head mounted display (HMD). The HMD refers to display techniques by which a display is mounted to a head to show an image directly in front of a user's eyes. In order to provide an image directly in front of the user's eyes when the user wears the glass-type mobile terminal 400, the display unit 451 may be located to correspond to either or both of the left and right eyes. FIG. 4 illustrates that the display unit 451 is located on a portion corresponding to the right eye to output an image viewable by the user's right eye.

The display unit 451 may project an image into the user's eye using a prism. Also, the prism may be formed from optically transparent material such that the user can view both the projected image and a general visual field (a range that the user views through the eyes) in front of the user.

In such a manner, the image output through the display unit 451 may be viewed while overlapping with the general visual field. The mobile terminal 400 may provide an augmented reality (AR) by overlaying a virtual image on a realistic image or background using the display.

The camera 421 may be located adjacent to either or both of the left and right eyes to capture an image. Since the camera 421 is located adjacent to the eye, the camera 421 can acquire a scene that the user is currently viewing.

The camera 421 may be positioned at most any location of the mobile terminal. In some embodiments, multiple cameras 421 may be utilized. Such multiple cameras 421 may be used to acquire a stereoscopic image.

The glass-type mobile terminal 400 may include user input units 423a and 423b, which can each be manipulated by the user to provide an input. The user input units 423a and 423b may employ techniques which permit input via a tactile input. Typical tactile inputs include a touch, push, or the like. The user input units 423a and 423b are shown operable in a pushing manner and a touching manner as they are located on the frame part and the control module 480, respectively.

If desired, mobile terminal 400 may include a microphone which processes input sound into electric audio data, and an audio output module 452 for outputting audio. The audio output module 452 may be configured to produce audio in a general audio output manner or an osteoconductive manner. When the audio output module 452 is implemented in the osteoconductive manner, the audio output module 452 may be closely adhered to the head when the user wears the mobile terminal 400 and vibrate the user's skull to transfer sounds.

A communication system which is operable with the variously described mobile terminals will now be described in more detail.

Such a communication system may be configured to utilize any of a variety of different air interfaces and/or physical layers. Examples of such air interfaces utilized by the communication system include Frequency Division Multiple Access (FDMA), Time Division Multiple Access (TDMA), Code Division Multiple Access (CDMA), Universal Mobile Telecommunications System (UMTS) (including, Long Term Evolution (LTE), LTE-A (Long Term Evolution-Advanced)), Global System for Mobile Communications (GSM), and the like.

By way of a non-limiting example only, further description will relate to a CDMA communication system, but such teachings apply equally to other system types including a CDMA wireless communication system as well as OFDM (Orthogonal Frequency Division Multiplexing) wireless communication system.

A CDMA wireless communication system generally includes one or more mobile terminals (MT or User Equipment, UE) 100, one or more base stations (BSs, NodeB, or evolved NodeB), one or more base station controllers (BSCs), and a mobile switching center (MSC). The MSC is configured to interface with a conventional Public Switched Telephone Network (PSTN) and the BSCs. The BSCs are coupled to the base stations via backhaul lines. The backhaul lines may be configured in accordance with any of several known interfaces including, for example, E1/T1, ATM, IP, PPP, Frame Relay, HDSL, ADSL, or xDSL. Hence, the plurality of BSCs can be included in the CDMA wireless communication system.

Each base station may include one or more sectors, each sector having an omni-directional antenna or an antenna pointed in a particular direction radially away from the base station. Alternatively, each sector may include two or more different antennas. Each base station may be configured to support a plurality of frequency assignments, with each frequency assignment having a particular spectrum (e.g., 1.25 MHz, 5 MHz, etc.).

The intersection of sector and frequency assignment may be referred to as a CDMA channel. The base stations may also be referred to as Base Station Transceiver Subsystems (BTSs). In some cases, the term “base station” may be used to refer collectively to a BSC, and one or more base stations. The base stations may also be denoted as “cell sites.” Alternatively, individual sectors of a given base station may be referred to as cell sites.

A broadcasting transmitter (BT) transmits a broadcast signal to the mobile terminals 100 operating within the system. The broadcast receiving module 111 of FIG. 1A is typically configured inside the mobile terminal 100 to receive broadcast signals transmitted by the BT.

Global Positioning System (GPS) satellites for locating the position of the mobile terminal 100, for example, may cooperate with the CDMA wireless communication system. Useful position information may be obtained with greater or fewer satellites than two satellites. It is to be appreciated that other types of position detection technology, (i.e., location technology that may be used in addition to or instead of GPS location technology) may alternatively be implemented. If desired, at least one of the GPS satellites may alternatively or additionally be configured to provide satellite DMB transmissions.

The location information module 115 is generally configured to detect, calculate, or otherwise identify a position of the mobile terminal. As an example, the location information module 115 may include a Global Position System (GPS) module, a Wi-Fi module, or both. If desired, the location information module 115 may alternatively or additionally function with any of the other modules of the wireless communication unit 110 to obtain data related to the position of the mobile terminal.

Atypical GPS module 115 can measure an accurate time and distance from three or more satellites, and accurately calculate a current location of the mobile terminal according to trigonometry based on the measured time and distances. A method of acquiring distance and time information from three satellites and performing error correction with a single satellite may be used. In particular, the GPS module may acquire an accurate time together with three-dimensional speed information as well as the location of the latitude, longitude and altitude values from the location information received from the satellites. Furthermore, the GPS module can acquire speed information in real time to calculate a current position. Sometimes, accuracy of a measured position may be compromised when the mobile terminal is located in a blind spot of satellite signals, such as being located in an indoor space. In order to minimize the effect of such blind spots, an alternative or supplemental location technique, such as Wi-Fi Positioning System (WPS), may be utilized.

The Wi-Fi positioning system (WPS) refers to a location determination technology based on a wireless local area network (WLAN) using Wi-Fi as a technology for tracking the location of the mobile terminal 100. This technology typically includes the use of a Wi-Fi module in the mobile terminal 100 and a wireless access point for communicating with the Wi-Fi module.

The Wi-Fi positioning system may include a Wi-Fi location determination server, a mobile terminal, a wireless access point (AP) connected to the mobile terminal, and a database stored with wireless AP information.

The mobile terminal connected to the wireless AP may transmit a location information request message to the Wi-Fi location determination server.

The Wi-Fi location determination server extracts the information of the wireless AP connected to the mobile terminal 100, based on the location information request message (or signal) of the mobile terminal 100. The information of the wireless AP may be transmitted to the Wi-Fi location determination server through the mobile terminal 100, or may be transmitted to the Wi-Fi location determination server from the wireless AP.

The information of the wireless AP extracted based on the location information request message of the mobile terminal 100 may include one or more of media access control (MAC) address, service set identification (SSID), received signal strength indicator (RSSI), reference signal received Power (RSRP), reference signal received quality (RSRQ), channel information, privacy, network type, signal strength, noise strength, and the like.

The Wi-Fi location determination server may receive the information of the wireless AP connected to the mobile terminal 100 as described above, and may extract wireless AP information corresponding to the wireless AP connected to the mobile terminal from the pre-established database. The information of any wireless APs stored in the database may be information such as MAC address, SSID, RSSI, channel information, privacy, network type, latitude and longitude coordinate, building at which the wireless AP is located, floor number, detailed indoor location information (GPS coordinate available), AP owner's address, phone number, and the like. In order to remove wireless APs provided using a mobile AP or an illegal MAC address during a location determining process, the Wi-Fi location determination server may extract only a predetermined number of wireless AP information in order of high RSSI.

Then, the Wi-Fi location determination server may extract (analyze) location information of the mobile terminal 100 using at least one wireless AP information extracted from the database.

A method for extracting (analyzing) location information of the mobile terminal 100 may include a Cell-ID method, a fingerprint method, a trigonometry method, a landmark method, and the like.

The Cell-ID method is used to determine a position of a wireless AP having the largest signal strength, among peripheral wireless AP information collected by a mobile terminal, as a position of the mobile terminal. The Cell-ID method is an implementation that is minimally complex, does not require additional costs, and location information can be rapidly acquired. However, in the Cell-ID method, the precision of positioning may fall below a desired threshold when the installation density of wireless APs is low.

The fingerprint method is used to collect signal strength information by selecting a reference position from a service area, and to track a position of a mobile terminal using the signal strength information transmitted from the mobile terminal based on the collected information. In order to use the fingerprint method, it is common for the characteristics of radio signals to be pre-stored in the form of a database.

The trigonometry method is used to calculate a position of a mobile terminal based on a distance between coordinates of at least three wireless APs and the mobile terminal. In order to measure the distance between the mobile terminal and the wireless APs, signal strength may be converted into distance information, Time of Arrival (ToA), Time Difference of Arrival (TDoA), Angle of Arrival (AoA), or the like may be taken for transmitted wireless signals.

The landmark method is used to measure a position of a mobile terminal using a known landmark transmitter.

In addition to these position location methods, various algorithms may be used to extract (analyze) location information of a mobile terminal.

Such extracted location information may be transmitted to the mobile terminal 100 through the Wi-Fi location determination server, thereby acquiring location information of the mobile terminal 100.

The mobile terminal 100 can acquire location information by being connected to at least one wireless AP. The number of wireless APs required to acquire location information of the mobile terminal 100 may be variously changed according to a wireless communication environment within which the mobile terminal 100 is positioned.

As previously described with regard to FIG. 1A, the mobile terminal may be configured to include short-range communication techniques such as Bluetooth™, Radio Frequency Identification (RFID), Infrared Data Association (IrDA), Ultra Wideband (UWB), ZigBee, Near Field Communication (NFC), Wireless USB (Wireless Universal Serial Bus), and the like.

A typical NFC module provided at the mobile terminal supports short-range wireless communication, which is a non-contactable type of communication between mobile terminals and generally occurs within about 10 cm. The NFC module may operate in one of a card mode, a reader mode, or a P2P mode. The mobile terminal 100 may further include a security module for storing card information, in order to operate the NFC module in a card mode. The security module may be a physical medium such as Universal Integrated Circuit Card (UICC) (e.g., a Subscriber Identification Module (SIM) or Universal SIM (USIM)), a secure micro SD and a sticker, or a logical medium (e.g., embedded Secure Element (SE)) embedded in the mobile terminal. Single Wire Protocol (SWP)-based data exchange may be performed between the NFC module and the security module.

In a case where the NFC module operates in a card mode, the mobile terminal may transmit card information on a general IC card to the outside. More specifically, if a mobile terminal having card information on a payment card (e. g, a credit card or a bus card) approaches a card reader, a short-range mobile payment may be executed. As another example, if a mobile terminal which stores card information on an entrance card approaches an entrance card reader, an entrance approval procedure may start. A card such as a credit card, a traffic card, or an entrance card may be included in the security module in the form of applet, and the security module may store card information on the card mounted therein. Card information for a payment card may include any of a card number, a remaining amount and usage history, and the like. Card information of an entrance card may include any of a user's name, a user's number (e.g., undergraduate number or staff number), an entrance history, and the like.

When the NFC module operates in a reader mode, the mobile terminal can read data from an external tag. The data received from the external tag by the mobile terminal may be coded into the NFC Data Exchange Format defined by the NFC Forum. The NFC Forum generally defines four record types. More specifically, the NFC Forum defines four Record Type Definitions (RTDs) such as smart poster, text, Uniform Resource Identifier (URI), and general control. If the data received from the external tag is a smart poster type, the controller may execute a browser (e.g., Internet browser). If the data received from the external tag is a text type, the controller may execute a text viewer. If the data received from the external tag is a URI type, the controller may execute a browser or originate a call. If the data received from the external tag is a general control type, the controller may execute a proper operation according to control content.

In some cases in which the NFC module operates in a P2P (Peer-to-Peer) mode, the mobile terminal can execute P2P communication with another mobile terminal. In this case, Logical Link Control Protocol (LLCP) may be applied to the P2P communication. For P2P communication, connection may be generated between the mobile terminal and another mobile terminal. This connection may be categorized as a connectionless mode which ends after one packet is switched, and a connection-oriented mode in which packets are switched consecutively. For a typical P2P communication, data such as an electronic type name card, address information, a digital photo and a URL, a setup parameter for Bluetooth connection, Wi-Fi connection, etc. may be switched. The P2P mode can be effectively utilized in switching data of a small capacity, because an available distance for NFC communication is relatively short.

Embodiments related to a control method implemented in the above-configured mobile terminal shall be described with reference to the accompanying drawings as follows. It will be appreciated by those skilled in the art that various modifications and variations can be made in the present invention without departing from the spirit or scope of the inventions.

Hereinafter, embodiments of the present invention shall be described by taking the mobile terminal 100 shown in FIG. 1A as an example of a mobile terminal. Furthermore, it is a matter of course that a mobile terminal according to one embodiment of the present invention can be implemented as one of the mobile terminals 200, 300 and 400 shown in FIGS. 2 to 4.

Configuration Modules of a Mobile Terminal

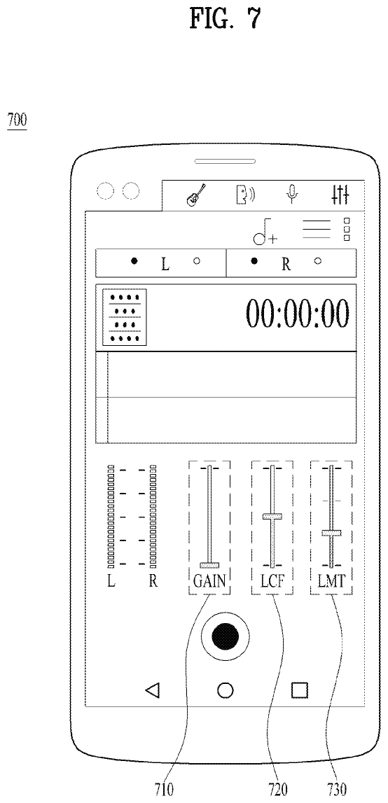

FIG. 5 is a block diagram showing configuration modules of a mobile terminal according to one embodiment of the present invention.

A mobile terminal 100 according to one embodiment of the present invention may include a display unit 510, an audio signal input unit 520 and a controller 530, by which configuration modules included in the mobile terminal are non-limited. And, various configuration modules may be further included in the mobile terminal.

First of all, the display unit 510 may output visual information. Here, the visual information may include a content, an application, an image, a video, an icon, a user interface, etc. The display unit 510 may output the visual information to a screen based on a control command of the controller 530. In the present invention, the display unit 510 may be implemented with the display unit 151 shown in FIG. 1A.

In the mobile terminal 500 according to one embodiment of the present invention, the display unit 510 may be implemented into a touchscreen by being combined with the input unit 120.

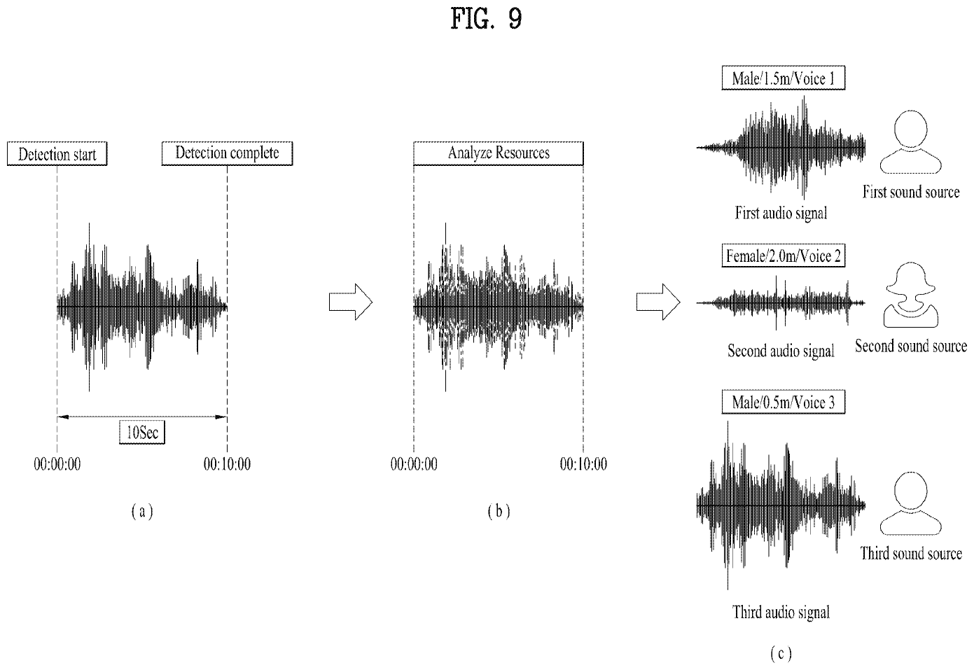

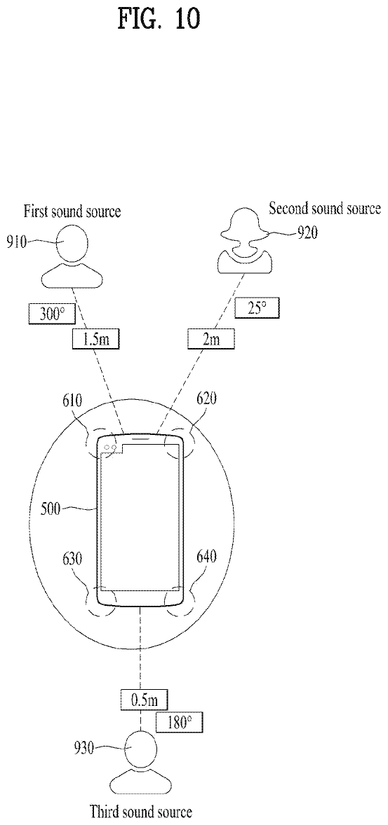

According to one embodiment of the present invention, in case that a recording application is launched, the display unit 510 can display a screen of the recording application. The screen of the recording application shall be described later with reference to FIG. 7 and FIG. 8.

The audio signal input unit 520 may receive an input of an audio signal. Particularly, the audio signal input unit 520 may be implemented with at least one microphone 122. In the present invention, the microphone included in the audio signal input unit 520 may be implemented with the microphone 122 shown in FIG. 1A.

The audio signal input unit 520 may convert an analog audio signal inputted through the at least one microphone 122 into an electrical audio signal.

Here, the audio signal inputted through the audio signal input unit 520 may include an audio signal generated from at least one sound source.

For one example, the audio signal may include an audio signal generated from a single sound source.

For another example, the audio signal may include an audio signal in which audio signals generated from a plurality of sound sources are mixed together.

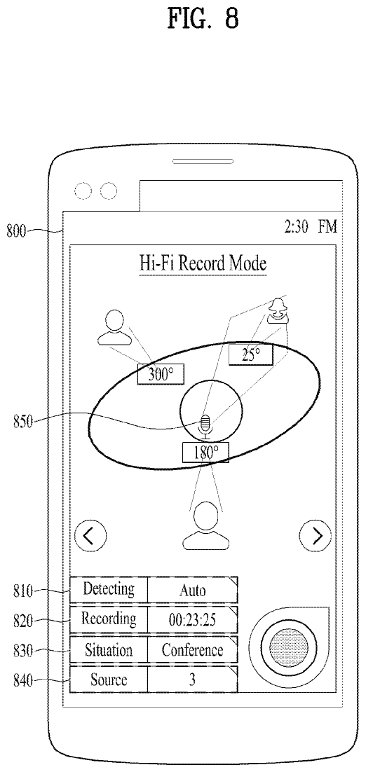

According to one embodiment of the present invention, the audio signal input unit 520 may include a plurality of the microphones 122, which shall be described with reference to FIG. 6 later.

The controller 530 may process data, control the above-described respective units of the mobile terminal, and control data transmission/reception among the units. In the present invention, the controller 530 may be implemented with the controller 180 shown in FIG. 1A.

According to one embodiment of the present invention, if a recording application is launched, the controller 530 can control the display unit 510 to display a screen of the recording application. The controller 530 can change a setting value of the recording application in response to a touch input to a specific indicator displayed on the screen. And, the controller 530 can at least one of a gain value of the microphone 122, a value for low-frequency noise cancellation, and a value for maximum volume limit using the changed setting value.

FIG. 6 is a diagram to describe a mobile terminal having a plurality of microphones.

According to one embodiment of the present invention, for precise sound recognition, the audio signal input unit 520 of the mobile terminal 500 may include a plurality of the microphones 122. Namely, the mobile terminal may include a plurality of microphones instead of a single microphone.

In some implementations, according to one embodiment of the present invention, the mobile terminal 500 may include 4 microphones that are directional microphones, by which the present invention is non-limited. And, it is obvious that the present invention is applicable to a case that a plurality of microphones are included.

Particularly, referring to FIG. 6, a first microphone may be located at a left top end 610 of a front part of a mobile terminal, a second microphone may be located at a right top end 620 of the front part of the mobile terminal, a third microphone may be located at a left bottom end 630 of the front part of the mobile terminal, and a fourth microphone may be located at a right bottom end 640 of the front part of the mobile terminal.

According to one embodiment of the present invention, as the audio signal input unit 520 is provided with a plurality of the microphones 122, a region of sensing audio may differ per microphone. Therefore, the microphone provided to the mobile terminal 500 of the present invention may correspond to a directional microphone capable of selectively sensing audio heard from a specific direction.

For example, a microphone located on a left side of the mobile terminal 500 can mainly sense audio generated form a left side of the mobile terminal 500, and a microphone located on a right side of the mobile terminal 500 can mainly sense audio generated form a right side of the mobile terminal 500.

Meanwhile, according to one embodiment of the present invention, the controller 530 can recognize a location of a sound source of an audio signal inputted through the audio signal input unit 520 using a plurality of the microphones.

Namely, since the first to fourth microphones are disposed in different regions, respectively, it is able to finely sense a location of a sound source of an audio signal inputted from various directions. The mobile terminal 500 can recognize 8 directions, in which sound is generated, through the combination of a plurality of the directional microphones.

For one example, if sound is sensed by the first and second microphones only among the first to fourth microphones and a size of the sound sensed by the first microphone is greater than that of the sound sensed by the second microphone, the controller 530 can recognize that the sound was generated from the direction in which the first microphone is located.

For another example, if sound is sensed by the third and fourth microphones only among the first to fourth microphones and a size of the sound sensed by the third microphone is equal to that of the sound sensed by the fourth microphone, the controller 530 can recognize that the sound was generated from a bottom side of the mobile terminal 500.

Eventually, according to one embodiment of the present invention, as the mobile terminal 500 includes a plurality of microphones, it is able to recognize sound was generated in which direction. Advantageously, by adjusting a gain value of a specific one of a plurality of the microphones, it is able to record sound generated in a specific direction more loudly.

Running Screen of a Recording Application

According to the present invention, the mobile terminal 500 may have a recording application stored in the memory. Here, the recording application may be stored in the memory since the shipping date, installed during an application program or firmware update, or separately stored in the memory by a user.

In response to an execution command of the recording application stored in the memory, the controller 530 may control the display unit 510 to display a running screen of the recording application stored in the memory. This shall be described in detail with reference to FIG. 7 and FIG. 8.

FIG. 7 is a diagram to describe one example of a running screen of a recording application according to one embodiment of the present invention.

According to one embodiment of the present invention, a running screen 700 of a recording application may include a plurality of indicators for changing the setting values of the recording application.

Particularly, referring to FIG. 7, the running screen 700 may include at least one of a first indicator 710 for changing a gain value of a microphone, a second indicator 720 for setting a value for low frequency noise cancellation, and a third indicator 730 for setting a value for a maximum volume limit.

The first indicator 710 is the indicator for adjusting sensitivity of sound recorded through a microphone.

For example, if a user sets a value of the first indicator 710 to a high value, a small sound can be sensed sensitively through the microphone.

The second indicator 720 is the indicator used to filter noise of a low frequency.

For example, if a user sets a value of the second indicator 720 to a high value, high frequency noise is filtered. If a value of the second indicator is set to a low value, noise of a low frequency such as an air conditioner sound is filtered only.

The third indicator 730 is the indicator used to prevent distortion of a big sound generated suddenly.

For example, if a user sets a value of the third indicator 730 to a high value, distortion of a small sound is prevented as well.

According to one embodiment of the present invention, a user can obtain a user-desired recording by changing various setting values of a recording application.

Yet, ordinary users who are not recording experts have difficulty in obtaining information indicating what kind of a result is obtained if changing various setting values of a recording application. Therefore, there is a problem that ordinary users fail to utilize the aforementioned setting values correctly. In the following description, a running screen of a recording application is proposed to solve the above-described problem.

FIG. 8 is a diagram to describe another example of a running screen of a recording application according to one embodiment of the present invention.

According to one embodiment of the present invention, the controller 530 can control the display unit 510 to display a running screen 800 of a recording application.

According to one embodiment of the present invention, the controller 530 can control the display unit 510 to display presence or non-presence of activation of a sound source detection function on a first region 810 within the running screen 800.

For one example, if a word ‘auto’ is displayed on the first region 810, a user can recognize that the sound source detection function is activated.

For another example, if a word ‘manual’ is displayed on the first region 810, a user can recognize that the sound source detection function is deactivated.

If a recording is executed, the controller 530 can control the display unit 510 to display information indicating a recording time on a second region 820 within the running screen 800.

The controller 530 can control the display unit 510 to display information on a current situation on a third region 830 within the running screen 800.

For example, if an audio signal is recorded during a conference, information (e.g., conference) indicating a conference can be displayed on the third region 830.

Particularly, the controller 530 analyzes an audio signal inputted through the audio signal input unit 520, thereby being able to recognize information on a current situation. The controller 530 can control the display unit 510 to display the recognized information on the current situation on the third region 830 within the running screen 800.

The controller 530 can control the display unit 510 to display information on the number of sound sources on a fourth region 840. Here, the information on the number of the sound sources is the information indicating the number of sound sources from which an audio signal is inputted. For example, in case of recording conversation contents of 3 speakers, information indicating ‘3’ can be displayed on the fourth region 840.

Particularly, the controller 530 analyzes an audio signal inputted through the audio signal input unit 520, thereby being able to recognize information indicating the number of sound sources from which the audio signal is inputted. The controller 530 can control the display unit 510 to display the recognized information on the fourth region 840 within the running screen 800.

In some implementations, the controller 530 can control the display unit 510 to display a specific indicator 850 related to a change of the setting value of the recording application on a specific region of the screen. A user can change the setting value of the recording application by moving the specific indicator 850.

Particularly, in case of detecting a touch input of touching & dragging the specific indicator 850, the controller 530 can change the setting value in response to the touch input.

Here, the setting value may include at least one of a gain value of a microphone, a value for low frequency noise cancellation and a value for a maximum volume limit. Moreover, in case that the audio signal input unit 520 includes a plurality of microphones, a gain value of each of a plurality of the microphones may be changed according to a movement of the specific indicator 850.

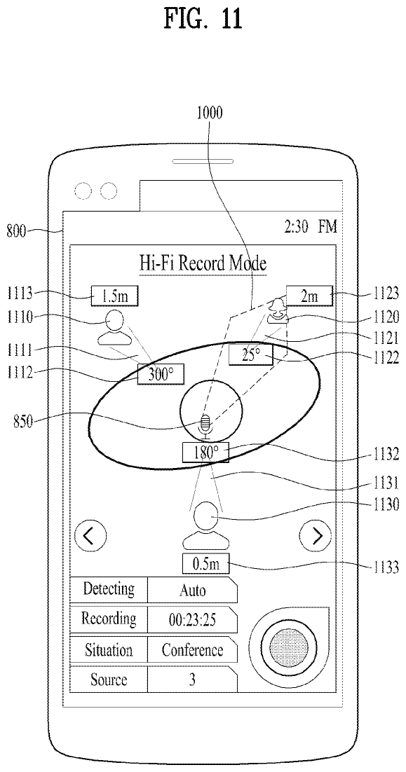

In case that a sound source detection function of the recording application is activated, the controller 530 can recognize information on a sound source of an audio signal inputted through the audio signal input unit 520 and control the display unit to display the recognized information on the sound source. This shall be described in detail with reference to FIGS. 9 to 11.

Method of Recognizing Information on a Sound Source

FIG. 9 is a diagram to describe one example of a method of recognizing information on a sound source in a mobile terminal according to one embodiment of the present invention.

In case of receiving an audio single through the audio signal input unit 520 according to a recording command, the controller 530 can analyze the audio signal inputted for a preset time.

Particularly, referring to FIG. 9 (a), the controller 530 can analyze an audio signal inputted through the audio signal input unit 520 for a preset time (e.g., 10 seconds). Here, the preset time can be changed by user settings.

Referring to FIG. 9 (b), the controller 830 analyzes the audio signal for the preset time, thereby being able to recognize whether the audio signal includes an audio signal of a plurality of sound sources or an audio signal of a single sound source.

Meanwhile, referring to FIG. 9 (c), if recognizing that the audio signal inputted through the audio signal input unit 520 for the preset time includes the audio signal of a plurality of the sound sources, the controller 830 can extract audio signals generated from a plurality of the sound sources, respectively.

Particularly, if a first audio signal of a first sound source, a second audio signal of a second sound source and a third audio signal of a third sound source are included in the audio signal inputted through the audio signal input unit 520, the controller 830 can extract the first to third audio signals from the audio signal inputted through the audio signal input unit 520.

Meanwhile, the controller 830 can obtain information on the sound source using the extracted first to third audio signals.

For one example, the controller 830 can recognize a gender of a sound source by recognizing a tone of each of a plurality of the sound sources.

Particularly, if recognizing that the tones of the first and third audio signals correspond to a tone of a male, the controller 830 can recognize that a gender of the sound source of each of the first and third audio signals is a male. And, if recognizing that the tone of the second audio signal corresponds to a tone of a female, the controller 830 can recognize that a gender of the sound source of the second audio signal is a female.

For another example, the controller 530 can recognize a distance between each of a plurality of the sound sources and the mobile terminal 500.

Particularly, the controller 180 can recognize a width of a register of each of the first to third sound sources using the first to third audio signals. And, the controller 530 can recognize a location of each of a plurality of the first to third sound sources spaced apart from the mobile terminal using the width of the register of each of the first to third sound sources. Here, an algorithm for recognizing a location of a sound source spaced apart from the mobile terminal using a width of a register may be stored in the memory.

Furthermore, the mobile terminal 500 can recognize a location spaced apart from the mobile terminal 500 by various methods using the extracted audio signals. And, the mobile terminal 500 may recognize a location of a sound source spaced apart from the mobile terminal using various sensors included in the sensing unit.

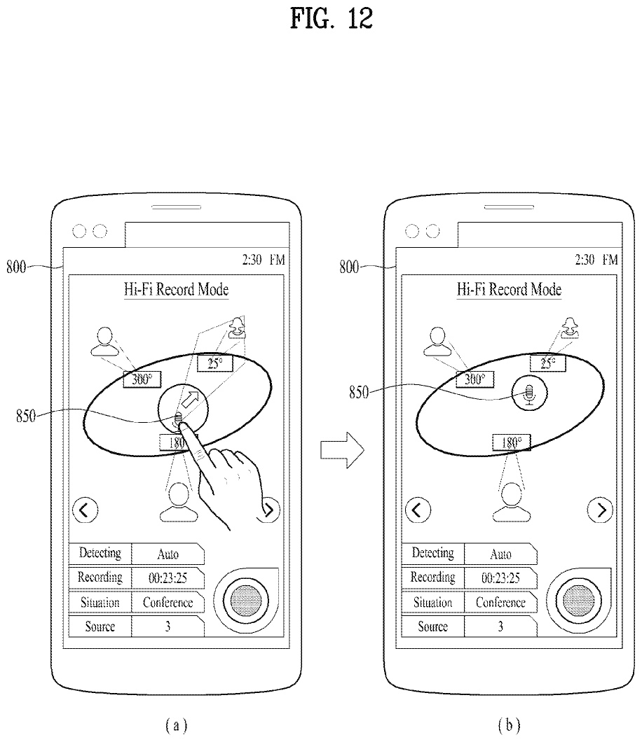

For further example, the controller 530 can recognize a location of each of a plurality of the sound sources. This shall be described in detail with reference to FIG. 10.

FIG. 10 is a diagram to describe one example of a method of recognizing a location of each of a plurality of sound sources in a mobile terminal according to one embodiment of the present invention. Regarding FIG. 10, the contents redundant with the former description with reference to FIG. 9 will not be described again and the following description shall be made by focusing on differences.

According to one embodiment of the present invention, the mobile terminal 500 may be provided with 4 microphones. A first microphone may be located at a left top end 610 of a front part of a mobile terminal, a second microphone may be located at a right top end 620 of the front part of the mobile terminal, a third microphone may be located at a left bottom end 630 of the front part of the mobile terminal, and a fourth microphone may be located at a right bottom end 640 of the front part of the mobile terminal. Furthermore, the mobile terminal 500 may be provided with a plurality of microphones.

According to one embodiment of the present invention, in case that a sound source detection function is activated, the controller 530 can detect a location of a sound source in response to a recording command.

Particularly, the controller 530 can recognize a distance between each of a plurality of the sound sources and the mobile terminal 500. And, the controller 530 recognizes that an audio signal is obtained through which one of the 4 microphones, thereby being able to recognize a direction of each of a plurality of the sound sources. Using the recognized distances and directions, the controller 530 can recognize locations of a plurality of the sound sources, respectively.

For one example, referring to FIG. 10, if a first audio signal of a first sound source 910 is sensed loudest by the first microphone, the controller 530 can recognize that the first sound resource 910 is located in a direction of a left top end 610 of the mobile terminal. And, the controller 530 can recognize a location of the first sound source 910 using a distance between the first sound source 910 and the mobile terminal 500 and the direction of the first sound source 910.

For another example, if a second audio signal of a second sound source 920 is sensed loudest by the second microphone, the controller 530 can recognize that the second sound resource 920 is obtained in a direction of a right top end 620 of the mobile terminal. And, the controller 530 can recognize a location of the second sound source 920 using a distance between the second sound source 920 and the mobile terminal 500 and the direction of the second sound source 920.

For further example, if a third audio signal of a third sound source 930 is sensed loudest by the third microphone and the fourth microphone, the controller 530 can recognize that the third sound resource 930 is obtained in a bottom direction of the mobile terminal. And, the controller 530 can recognize a location of the third sound source 930 using a distance between the third sound source 930 and the mobile terminal 500 and the direction of the third sound source 930.

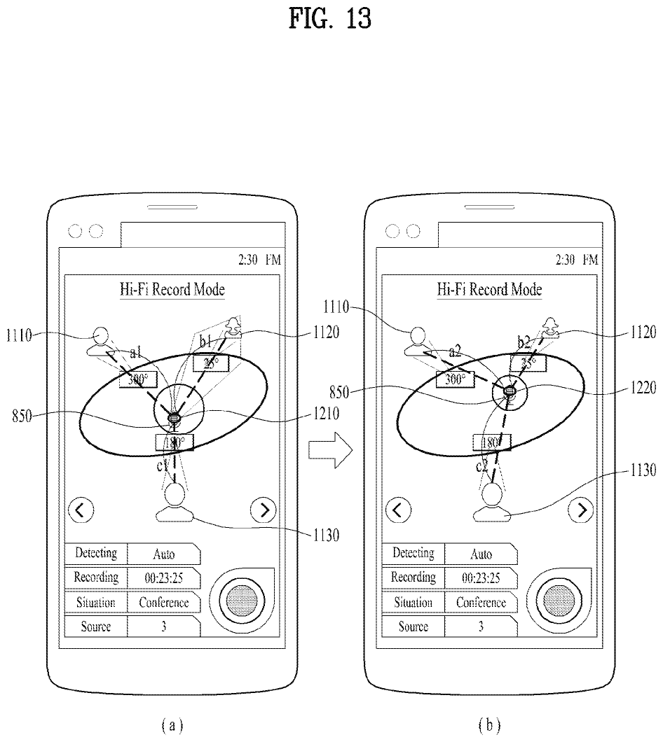

In some implementations, according to one embodiment of the present invention, the controller 530 can control the display unit 510 to display information on a sound source recognized in FIG. 9 and FIG. 10 on a running screen of a recording application. This is described in detail with reference to FIG. 11.

Method of Displaying Information on a Sound Source

FIG. 11 is a diagram to describe one example of a method of displaying information on a sound source in a mobile terminal according to one embodiment of the present invention. Regarding FIG. 11, the contents redundant with the former description with reference to FIGS. 8 to 10 will not be described again and the following description shall be made by focusing on differences.

Regarding FIG. 11, the following description shall be made on the assumption that an audio signal inputted through the audio signal input unit 520 includes a first audio signal of a first sound source, a second audio signal of a second sound source and a third audio signal of a third sound source.

According to one embodiment of the present invention, the controller 530 can control the display unit 510 to display a first image 1110 corresponding to the first sound source, a second image 1120 corresponding to the second sound source and a third image 1130 corresponding to the third sound source on a running screen 800 of a recording application. Here, the first image 1110, the second image 1120 and the third image 1130 can be displayed on regions corresponding to locations of a plurality of the sound sources, respectively.

First of all, the controller 530 can control the display unit 510 to display a specific indicator 850 related to a change of a setting value of the recording application on a specific region (e.g., a central region within the running screen) on the running screen. Here, although the specific indicator 850 is an indicator for changing the setting value, it may be used as a reference for indicating locations of the mobile terminal 500 and the sound source.

If recognizing that a location of the first source is located in a left top end direction of the mobile terminal and at a distance of 1.5 m from the mobile terminal, the controller 530 can recognize a region corresponding to the location and direction within the running screen 800. And, the controller 530 can control the display unit 510 to display the first image 1110 on the recognized region.

If recognizing that a location of the second source is located in a left top end direction of the mobile terminal 500 and at a distance of 2 m from the mobile terminal, the controller 530 can recognize a region corresponding to the location and direction within the running screen 800. And, the controller 530 can control the display unit 510 to display the second image 1120 on the recognized region.

If recognizing that a location of the third source is located in a bottom direction of a front part of the mobile terminal 500 and at a distance of 0.5 m from the mobile terminal, the controller 530 can recognize a region corresponding to the location and direction within the running screen 800. And, the controller 530 can control the display unit 510 to display the third image 1130 on the recognized region.

Since a distance between the second source and the mobile terminal 500 is greater than that between the first sound source and the mobile terminal 500, a length from the region having the specific indicator 850 displayed thereon to the region having the second image 1120 displayed thereon may be greater than a length from the region having the specific indicator 850 displayed thereon to the region having the first image 1110 displayed thereon. Hence, a user compares a length between the region on which an image corresponding to one of a plurality of sound sources is displayed and the region having the specific indicator 850 displayed thereon with a length between the region on which an image corresponding to another one of a plurality of sound sources is displayed and the region having the specific indicator 850 displayed thereon, thereby recognizing how far each of a plurality of the sound sources is distant from the mobile terminal 500.

In some implementations, according to one embodiment of the present invention, the controller 530 can control the display unit 510 to display a first information on a direction in which each of a plurality of sound sources is located and a second information on a distance between each of a plurality of the sound sources and the mobile terminal.

Particularly, the controller 530 can control the display unit 510 to display an information 1111 indicating a direction of the first sound source, an information 1112 indicating that the first sound source is located in a direction at 300° clockwise centering on the center of the top end of the mobile terminal 500, and an information 1113 indicating that the first sound source is located at a distance of 1.5 m from the mobile terminal around the region having the first image 1110 displayed thereon.

And, the controller 530 can control the display unit 510 to display an information 1121 indicating a direction of the second sound source, an information 1122 indicating that the second sound source is located in a direction at 25° clockwise centering on the center of the top end of the mobile terminal 500, and an information 1123 indicating that the second sound source is located at a distance of 2 m from the mobile terminal around the region having the second image 1120 displayed thereon.

Moreover, the controller 530 can control the display unit 510 to display an information 1131 indicating a direction of the third sound source, an information 1132 indicating that the first sound source is located in a direction at 180° clockwise centering on the center of the top end of the mobile terminal 500, and an information 1133 indicating that the third sound source is located at a distance of 0.5 m from the mobile terminal around the region having the third image 1110 displayed thereon.

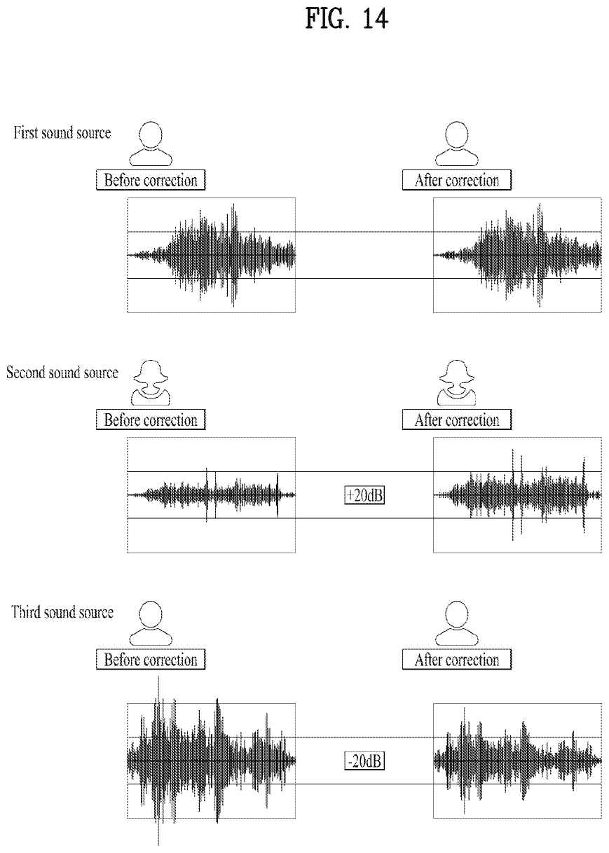

In some implementations, according to one embodiment of the present invention, the controller 530 can move the specific indicator 850 in response to a touch input to the specific indicator 850. This shall be described in detail with reference to FIG. 12 later.

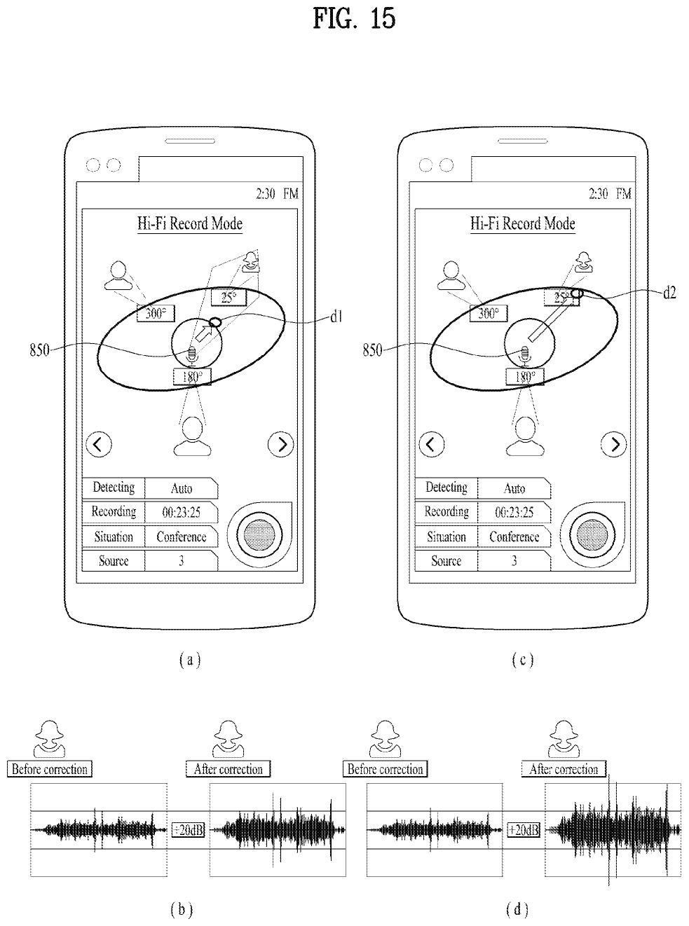

Meanwhile, after having moved the specific indicator 850, the controller 530 can change a setting value of the recording application so as to decrease a size of an audio signal of a sound source corresponding to an image getting closer to the specific indicator 850 among the first, second and third images 1110, 1120 and 1130. Moreover, after having moved the specific indicator 850, the controller 530 can change a setting value of the recording application so as to increase a size of an audio signal of a sound source corresponding to an image getting far away from the specific indicator 850 among the first, second and third images 1110, 1120 and 1130. This shall be described in detail with reference to FIG. 13 and FIG. 14 later.

Meanwhile, the controller 530 can recognize a preset setting value corresponding to a location of each of the first to third sound sources. And, the controller 530 can control the display unit 510 to display an information 1000 indicating a location and direction corresponding to the preset setting value on the screen 800, here, the preset setting value may include a most optimal setting value.

Particularly, information on a most optimal setting value corresponding to a location of each of a plurality of sound sources may be stored in the memory in advance. The controller 530 may recognize a location of each of the first to third sound sources and then extract the preset setting value corresponding to the recognized location from the memory. And, the controller 530 may display information indicating how much the specific indicator 850 should be moved in which direction to change the setting value into the preset value.

For example, in case that the controller 530 recognizes that the setting value is changed to correspond to the preset value only if moving the specific indicator 850 toward the region having the second image 1120 displayed thereon, the controller 530 can control the display unit 510 to display an information 1000 instructing that the specific indicator 850 needs to be moved toward the direction having the second image 1120 displayed therein.

Meanwhile, the controller 530 may recognize information on a volume level of an audio signal of each of the first to third sound sources and then determine sizes of the first, second and third images 1110, 1120 and 1130 based on the recognized information on the volume levels.

For example, if the volume level of the audio signal of the third sound source is highest and the volume level of the second sound source is lowest, the controller 530 can control the display unit 510 so as to enable the third image 1130 to be displayed in the largest size. And, the controller 530 can control the display unit 510 so as to enable the second image 1120 to be displayed in the smallest size.

Meanwhile, the controller 530 may recognize a tone of each of the first to third sound sources. And, the controller 530 may display images corresponding to the recognized tones as images corresponding to a plurality of sound sources, respectively.

For example, the controller 530 can recognize that the tones of the first and third sound sources correspond to male tones and that the tone of the second sound source corresponds to a female tone. The controller 530 may display the first image 1110 corresponding to the first sound source and the third image 1130 corresponding to the third sound source as images corresponding to males. And, the controller 530 may display the second image 1120 corresponding to the second sound source as an image corresponding to a female.

Method of Changing a Setting Value of a Recording Application

In some implementations, according to one embodiment of the present invention, the controller 530 can change a setting value of a recording application in response to a touch input to a specific indicator displayed on a running screen of the recording application. This shall be described in detail with reference to FIGS. 12 to 15 later.

Regarding FIGS. 12 to 15, the following description shall be made on the assumption that an audio signal inputted through the audio signal input unit 520 includes a first audio signal of a first sound source, a second audio signal of a second sound source and a third audio signal of a third sound source.

FIG. 12 is a diagram to describe one example of a method of moving a specific indicator for changing a setting value of a recording application in a mobile terminal according to one embodiment of the present invention.

According to one embodiment of the present invention, if an audio signal includes audio signals of a plurality of sound sources, the controller 530 may display an image corresponding to each of a plurality of sound sources on a running screen 800 of a recording application. The controller 530 can control the display unit 510 to display a specific indicator 850 related to a change of a setting value of the recording application on the running screen 800.

Meanwhile, the controller 530 may move a location having the specific indicator 850 displayed thereat in response to a touch input that moves the specific indicator 850.

Particularly, referring to FIG. 12 (a), the controller 530 may recognize a touch & drag input to the specific indicator 850. The controller 530 may recognize a drag direction and length of the touch & drag input. Referring to FIG. 12 (b), the controller 530 may move the specific indicator 850 to enable the specific indicator 850 to be displayed at a location having the drag ended thereat using the drag direction and length.

In some implementations, according to one embodiment of the present invention, a setting value of the recording application may be changed in response to a movement of the specific indicator 850. This is described in detail with reference to FIG. 13.

FIG. 13 and FIG. 14 are diagrams to describe one example of a method of changing a setting value of a recording application to change a size of an audio signal of each of a plurality of sound sources in a mobile terminal according to one embodiment of the present invention. Regarding FIG. 13 and FIG. 14, the contents redundant with the former description with reference to FIG. 12 will not be described again and the following description shall be made by focusing on differences.

According to one embodiment of the present invention, the controller 530 may change a setting value of a recording application in response to a movement of a specific indicator related to a change of the setting value of the recording application.

In response to a touch input for moving a specific indicator in a state that the specific indicator 850 is displayed on a first region 1210 [FIG. 13 (a)], the controller 530 may move the specific indicator 850 to a second region 1220 different from the first region 1210 [FIG. 13 (b)].

After the specific indicator 850 has been moved, the controller 530 may change the setting value based on a distance change between a region on which an image corresponding to each of a plurality of the sound sources is displayed and a region on which the specific indicator 850 is displayed. Here, the setting value may include at least one of a gain value of a microphone included in the audio signal input unit 510, a value for low frequency noise cancellation and a value for a maximum volume limit.

Particularly, the controller 530 may recognize a first distance a1 between the first region 1210 and the region having the first image 1110 displayed thereon before the specific indicator 850 is moved [FIG. 13 (a)]. After the specific indicator 850 has been moved [FIG. 13 (b)], the controller 530 may recognize a second distance a2 between the second region 1220 and the region having the first image 1110 displayed thereon. In case of recognizing that a distance between the first distance a1 and the second distance a2 is not changed, the controller 530 may configure the setting value so that a size of an audio signal of a first sound source corresponding to the first image 1110 is not changed. Namely, as shown in FIG. 14, the size of the first audio signal of the first sound source before correction may be equal to that of the first audio signal of the first sound source corrected by changing the setting value.

And, the controller 530 may recognize a third distance b1 between the first region 1210 and the region having the second image 1120 displayed thereon before the specific indicator 850 is moved [FIG. 13 (a)]. After the specific indicator 850 has been moved [FIG. 13 (b)], the controller 530 may recognize a fourth distance b2 between the second region 1220 and the region having the second image 1120 displayed thereon. In case of recognizing that the fourth distance is shorter by comparing the third distance b1 and the fourth distance b2 with each other, the controller 530 may recognize that the specific indicator gets closer to the second image 1120. And, the controller 530 may change the setting value so that a size of an audio signal of a sound source corresponding to the second image 1120 is increased. Namely, as shown in FIG. 14, a size of the second audio signal of the second sound source corrected by changing the setting value may become greater than that of the second audio signal of the second sound source before correction.

Moreover, the controller 530 may recognize a fifth distance c1 between the first region 1210 and the region having the third image 1130 displayed thereon before the specific indicator 850 is moved [FIG. 13 (a)]. After the specific indicator 850 has been moved [FIG. 13 (b)], the controller 530 may recognize a sixth distance c2 between the second region 1220 and the region having the third image 1130 displayed thereon. In case of recognizing that the sixth distance c2 is longer by comparing the fifth distance c1 and the sixth distance c2 with each other, the controller 530 may recognize that the specific indicator gets far away from the third image 1130. And, the controller 530 may change the setting value so that a size of an audio signal of a sound source corresponding to the third image 1130 is decreased. Namely, as shown in FIG. 14, a size of the third audio signal of the third sound source corrected by changing the setting value may become smaller than that of the third audio signal of the third sound source before correction.

Namely, the controller 530 may change the setting value so as to decrease a size of an audio signal of a sound source corresponding to an image getting far away from the specific indicator 850 among images respectively corresponding to a plurality of sound sources after moving the specific indicator 850 in response to a touch input of moving the specific indicator 850, change the setting value so as to increase a size of an audio signal of a sound source getting closer to the specific indicator 850, and configure the setting value so as not to change a size of an audio signal of a sound source corresponding to an image having no distance change from the specific indicator 850.

Meanwhile, in case that a plurality of microphones are included in the audio signal input unit 510, the controller 530 may change a gain value of each of a plurality of the microphones in response to a change of the setting value.

For example, in case that the mobile terminal 500 is implemented with 4 microphones like FIG. 6, the controller 530 may not change a gain value of a microphone located at a left top end of the front part of the mobile terminal 500 in order to maintain the first audio signal of the first sound source of FIG. 13. In order to change a size of the second audio signal of the second sound source of FIG. 13 increasingly, the controller 530 may increase a gain value of a microphone located at a right top end of the front part of the mobile terminal 500. In order to change a size of the third audio signal of the third sound source of FIG. 13 decreasingly, the controller 530 may decrease a gain value of a microphone located at each of left and right bottom ends of the front part of the mobile terminal 500.

Eventually, according to one embodiment of the present invention, although the first audio signal before correction, the second audio signal before correction and the third audio signal before correction are the actual audio signals of the first to third sound sources in FIG. 14, if a user moves the specific indicator 850, corrected first to third audio signals may be recorded as audio signals of the first to third sound sources, respectively. Namely, a corrected audio signal different from an actual audio signal may be recorded as an audio signal of each sound source.

According to one embodiment of the present invention, a user can advantageously record an audio signal generated from each sound source by correcting the generated audio signals overall through a simple touch input to the specific indicator 850.

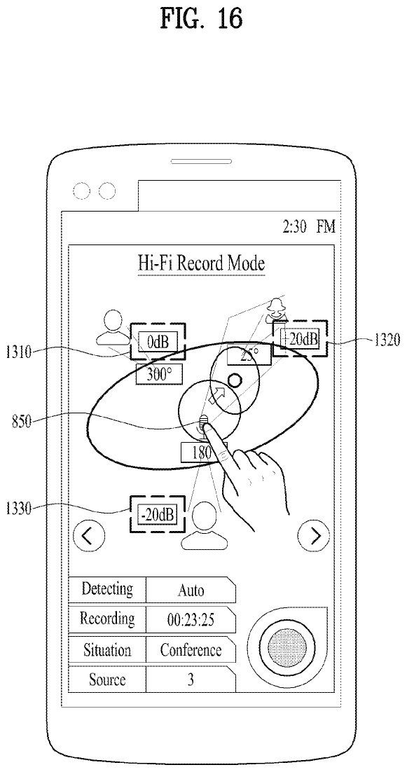

In some implementations, according to one embodiment of the present invention, the controller 530 may change the setting value in response to a length of a touch input to the specific indicator 850. This is described in detail with reference to FIG. 15.

FIG. 15 is a diagram to describe one example of a method of changing a setting value of a recording application to correspond to a length of a touch input of a specific indicator in a mobile terminal according to one embodiment of the present invention. Regarding FIG. 15, the contents redundant with the former description with reference to FIGS. 12 to 14 will not be described again and the following description shall be made by focusing on differences.

For clarity of the description of the present embodiment, the following description shall be made by being limited to a second sound source among a plurality of sound sources, by which the present invention is non-limited. And, the embodiment of the present invention is applicable to each of a plurality of the sound sources.

According to one embodiment of the present invention, the controller 530 may change a setting value of a recording application in response to a touch input to a specific indicator 850 related to a change of the setting value of the recording application. In this case, the touch input may include a touch & drag input to the specific indicator 850, and the controller 530 may change the setting value in response to a length of the drag.

Referring to FIG. 15 (a), the controller 530 may detect a touch input of touching the specific indicator 850 and dragging it by a first distance d1 in a direction in which an image corresponding to a second sound source is displayed. In this case, as shown in FIG. 15 (b), the controller 530 may change the setting value so that a size of an audio signal of the second sound source is increased by a size (e.g., 20 dB) corresponding to the first distance d1.

Referring to FIG. 15 (c), the controller 530 may detect a touch input of touching the specific indicator 850 and dragging it by a second distance d2 in a direction in which an image corresponding to a second sound source is displayed. In this case, as shown in FIG. 15 (d), the controller 530 may change the setting value so that a size of an audio signal of the second sound source is increased by a size (e.g., 40 dB) corresponding to the second distance d2.

Here, since a length of the second distance d2 is greater than that of the first distance d1, a size of the second audio signal of the second sound source corrected in FIG. 15 (d) may be greater than that of the second audio signal of the second sound source corrected in FIG. 15 (b).

Method of Displaying Information on a Changed Setting Value

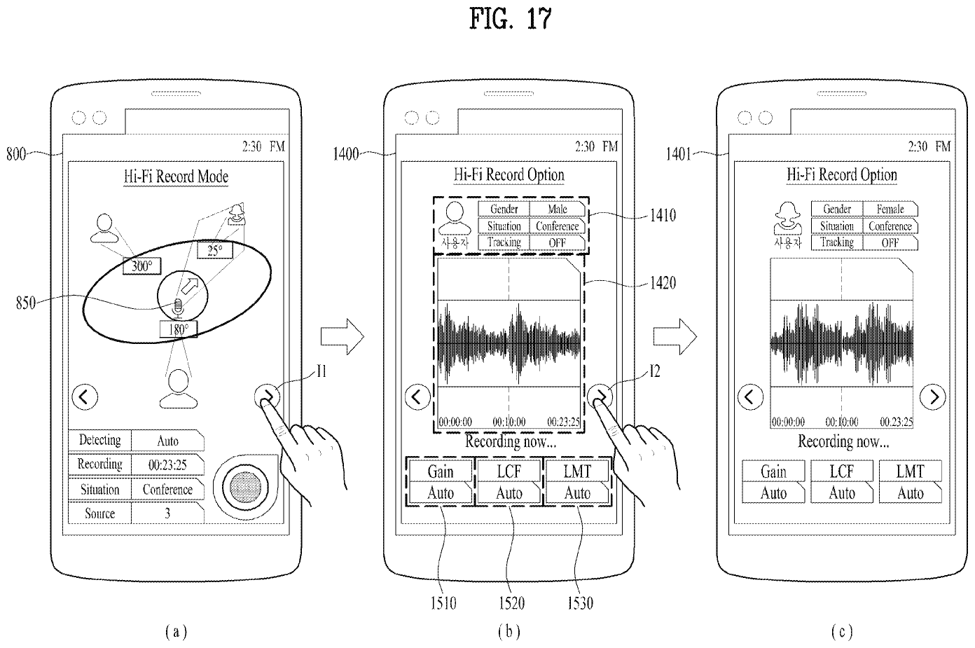

According to one embodiment of the present invention, if a size of each of the first to third audio signals is changed in response to a touch input to the specific indicator 850, the controller 530 may display information on the changed setting value on the screen. This is described in detail with reference to FIG. 16.

FIG. 16 is a diagram to describe one example of a method of displaying information on a setting value changed in response to a movement of a location of a specific indicator in a mobile terminal according to one embodiment of the present invention.

According to one embodiment of the present invention, in response to a touch input of touching a specific indicator 850 related to a setting value of a recording application displayed on a running screen of the recording application, the controller 530 may change the setting value so as to change a size of an audio signal of each of a plurality of sound sources. In this case, when the size of the audio signal of a plurality of the sound sources is changed, the controller 530 can control the display unit 510 to display information indicating an extent of the change.

Referring to FIG. 16, in response to a touch input of dragging the specific indicator 850 toward an image corresponding to a second sound source, the controller 530 may change the setting value so that a size of a second audio signal corresponding to the second source can be increased by 20 dB. In doing so, the controller 530 can control the display unit 510 to display an information 1320 indicating ‘+20 dB’ on an ambient region of the image corresponding to the second sound source. In this case, a user checks the information 1320, thereby being able to recognize that the audio signal of the second sound source is increased by 20 dB if moving the specific indicator 850.

And, in response to a touch input of dragging the specific indicator 850 in a direction getting far away from an image corresponding to a third sound source, the controller 530 may change the setting value so that a size of a third audio signal corresponding to the third source can be decreased by 20 dB. In doing so, the controller 530 can control the display unit 510 to display an information 1330 indicating ‘−20 dB’ on an ambient region of the image corresponding to the third sound source. In this case, a user checks the information 1330, thereby being able to recognize that the audio signal of the third sound source is decreased by 20 dB if moving the specific indicator 850.

Moreover, if recognizing that there is no change of a distance from an image corresponding to a first sound source despite moving the specific indicator 850 in response to a touch input to the specific indicator 850, the controller 530 can control the display unit 510 to display an information 1310 indicating that a size of a first audio signal corresponding to the first sound source is not changed. In this case, a user checks the information 1310, thereby being able to recognize that there is no change of a size of the audio signal of the first sound source despite that the specific indicator 850 is moved.

According to the present embodiment, if moving a specific indicator 850, a user can recognize how much a size of an audio signal corresponding to each of a plurality of sound sources is changed. Hence, the user can advantageously correct audio signals of a plurality of sound sources more accurately.

Method of Displaying Information on a Sound Source of Each of a Plurality of Sound Sources and Information on an Audio Signal of Each of a Plurality of the Sound Sources

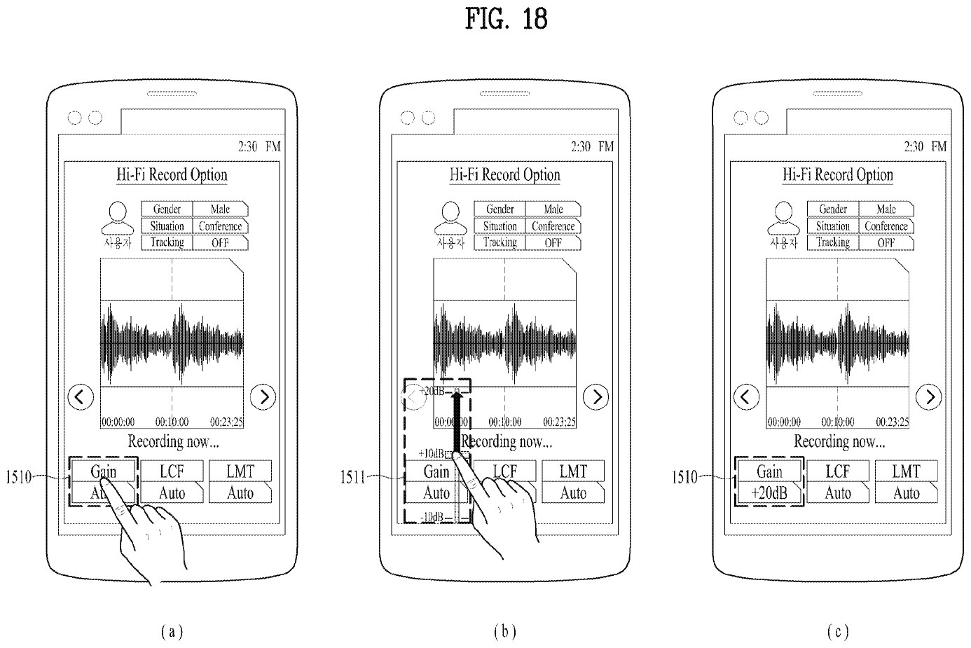

Meanwhile, according to one embodiment of the present invention, the controller 530 may change a running screen of a recording application in response to a specific input. A user may obtain information on a sound source of each of a plurality of sound sources and information on an audio signal of each of a plurality of the sound sources. This is described in detail with reference to FIG. 17.

FIG. 17 is a diagram to describe another example of a running screen of a recording application in a mobile terminal according to one embodiment of the present invention.

Regarding FIG. 17, the following description shall be made on the assumption that an audio signal inputted through the audio signal input unit 520 includes a first audio signal of a first sound source, a second audio signal of a second sound source and a third audio signal of a third sound source.

Referring to FIG. 17 (a), in a state that a first running screen 800 of a recording application is displayed, the controller 530 may detect a touch input of touching a running screen switch indicator 11 included in the first running screen 800.

In response to the touch input to the indicator 11, the controller 530 may change the first running screen 800 into a second running screen 1400.

Referring to FIG. 17 (b), the second running screen 1400 may include information on an audio signal of a specific one of a plurality of sound sources and information on the specific sound source.

For example, the controller 530 can control the display unit 510 to display the second running screen 1400 including information on a first sound source and information on a first audio signal of the first sound source in response to the touch input to the indicator 11.

Particularly, the controller 530 can control the display unit 510 to display information on a gender obtained using a tone of the first sound source, information on a current situation and information indicating whether a tracking function for the first audio signal is activated on a first region 1410 within the second running screen 1400. Moreover, the controller 530 may recognize a waveform of the first audio signal and control the display unit 510 to display the recognized waveform of the first audio signal on a second region 1420 within the second running screen 1400.

Meanwhile, in the second running screen 1400, a first indicator 1510 for adjusting a gain value of a microphone, a second indicator 1520 for adjusting a value for low frequency noise cancellation and a third indicator 1530 for adjusting a value for a maximum volume limit may be included.

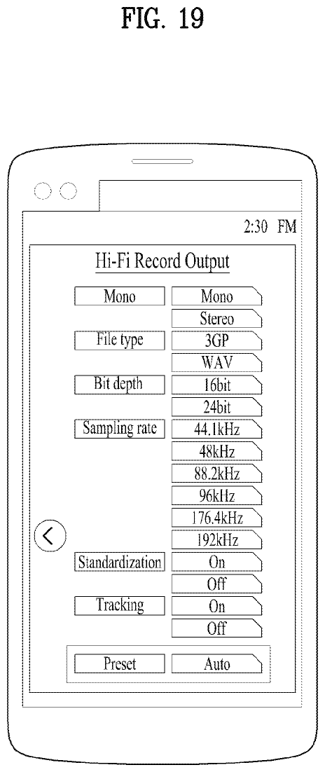

A user can change setting values of a recording application using the first, second and third indicators 1510, 1520 and 1530. This will be described in detail with reference to FIG. 18.

Meanwhile, at least one of a gain value of a microphone, a value for low frequency noise cancellation and a value for a maximum volume limit can be adjusted automatically. In this case, information (e.g., word ‘Auto’) indicating ‘automatic adjustment in progress’ may be displayed on at least one of the first, second and third indicators 1510, 1520 and 1530.

For example, in case that a gain value of a microphone, a value for low frequency noise cancellation and a value for a maximum volume limit are automatically adjusted, information indicating ‘automatic adjustment in progress’ may be displayed on of the first, second and third indicators 1510, 1520 and 1530.

Meanwhile, in response to a touch input of touching the running screen switch indicator 12 displayed on the second running screen 1400 in FIG. 17 (b), the controller 530 can control the display unit to display a third running screen 1401 like FIG. 17 (c). Here, the third running screen 1401 may include a running screen including information on the second sound source and information on a second audio signal of the second sound source. This is similar to the former description with reference to FIG. 17 (b), its details shall be omitted.

Namely, while the first running screen 800 of FIG. 17 (a) is displayed, if a user desires to check the information on the first audio signal and the information on the first sound source only, the user may just touch the screen switch indicator 11 displayed on the first running screen 800. If the user desires to check information on an audio signal different from the first audio signal and information on a sound source different from the first sound source, the user may just touch the screen switch indicator 12 displayed on the second running screen 800 of FIG. 17 (b).

According to the present embodiment, if an audio signal inputted through the audio signal input unit 520 includes audio signals of a plurality of sound sources, a user can be advantageously provided with information on each sound source and information on an audio signal of each sound source.

Method of Changing a Setting Value of an Audio Signal of a Specific Sound Source Only

According to one embodiment of the present invention, while a running screen including information on an audio signal of a specific one of a plurality of sound sources and information on the specific sound source is displayed, a user can change a setting value for the specific sound source only. This is described in detail with reference to FIG. 18.

FIG. 18 is a diagram to describe one example of a method of changing a setting value for an audio signal of a specific sound source in a mobile terminal according to one embodiment of the present invention.

Regarding FIG. 18, the following description shall be made on the assumption that an audio signal inputted through the audio signal input unit 520 includes a first audio signal of a first sound source, a second audio signal of a second sound source and a third audio signal of a third sound source.

Referring to FIG. 18 (a), while a running screen including information on the first audio signal and information on the first sound source is displayed, the controller 530 may detect a touch input of touching a first indicator 1510 for adjusting a gain value of a microphone.

In this case, the controller 530 can control the display unit 510 to display a specific indicator 1511 related to adjustment of the gain value. The specific indicator 1511 may be displayed around a region having the first indicator 1510 displayed thereon.

The controller 530 may detect a touch input of dragging the first indicator 1510 along the specific indicator. In response to the touch input, the controller 530 may adjust a gain value of a microphone that obtains the first audios signal of the first sound source.

For example, in case of detecting a touch input of touching the first indicator 1510 and then dragging it to a point at which information indicating ‘+20 dB’ is displayed along the specific indicator, the controller 530 may increase a gain value of the microphone, which obtains the first audio signal, up to 20 dB.

Meanwhile, referring to FIG. 18 (c), if the gain value is increased up to 20 dB, the controller 530 may display information on that changed gain value on the first indicator 1510.

Eventually, the controller 530 may change the setting value of the first audio signal in response to a change command of the setting value only.

The above-described embodiment of the present invention is non-limited to changing the gain value, and may be applicable to a case of changing a value for low frequency noise cancellation and a value for a maximum volume limit as well.

Meanwhile, according to the above-described embodiment, it is only described that t the setting value of the first audio signal is changed, by which the present invention is non-limited.

Particularly, if a setting value is changed in a state that information on a second sound source and a second audio signal is displayed within a currently displayed running screen, a setting value of the second audio signal can be changed only. And, if the setting value is changed in a state that information on a third sound source and a third audio signal is displayed within a currently displayed running screen, a setting value of the third audio signal may be changed only.

Menu for Changing Settings of a Recording Application

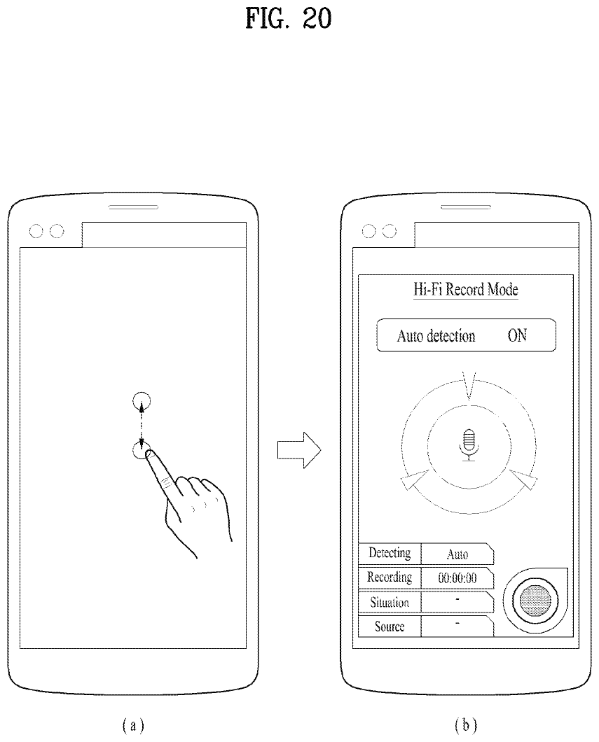

According to one embodiment of the present invention, a user can change settings of a recording application using a setting change menu of the recoding application. This is described in detail with reference to FIG. 19.

FIG. 19 is a diagram to describe one example of a method of changing a setting of a recording application through a setting change menu of a recording application in a mobile terminal according to one embodiment of the present invention.

Referring to FIG. 19, in response to an output command of a setting change menu, the controller 530 may control the display unit 510 to display a setting change menu of a recording application.

The setting change menu may include at least one of an indicator related to a channel setting, an indicator related to a file type setting, an indicator related to a bit depth setting, an indicator related to a setting of a sampling rate, an indicator for setting whether to activate standardization, an indicator for setting whether to activate audio signal tracking, and an indicator for setting whether to activate a function of changing a setting value of a recording application automatically.

A user selects a prescribed one of a plurality of indicators displayed on the setting change menu, thereby being able to change a setting of the recording application.

Method of Launching a Recording Application

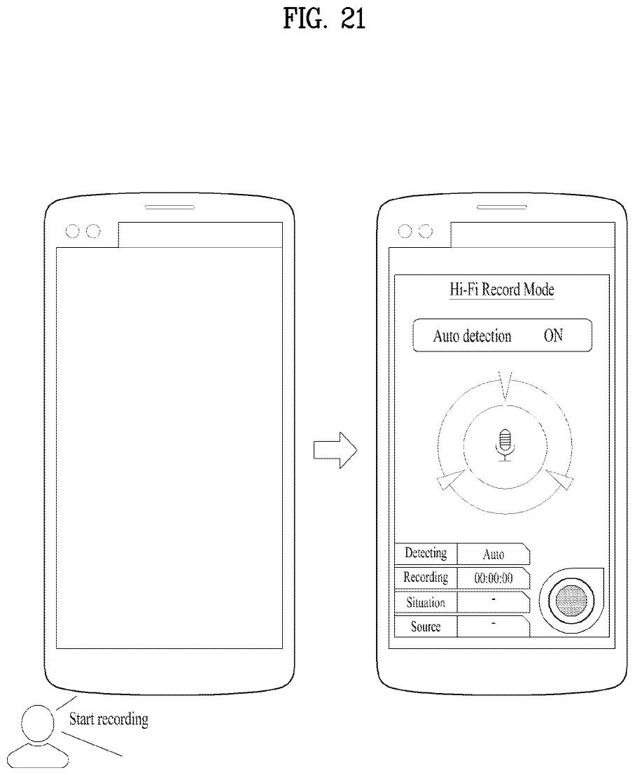

Meanwhile, according to one embodiment of the present invention, the controller 530 can launch a recording application if detecting a specific input in a state that the display unit 510 is deactivated. This is described in detail with reference to FIG. 20 and FIG. 21.

FIG. 20 and FIG. 21 are diagrams to describe examples of a method of launching a recording application in a deactivated state of a display unit in a mobile terminal according to one embodiment of the present invention.

According to one embodiment of the present invention, if a specific input is detected, the controller 530 may launch a recording application.

For one example, while the display unit 510 is deactivated, if a touch input of rubbing the display unit 510 is detected [FIG. 20 (a)], the controller 530 may activate the display unit 510 and launch a recording application. And, the controller 530 can control the display unit 510 to display a running screen of the recording application [FIG. 20 (b)].

For another example, while the display unit 510 is deactivated, if a specific audio signal (e.g., an audio signal indicating ‘start recording’) is inputted [FIG. 21 (a)], the controller 530 may activate the display unit 510 and launch a recording application. And, the controller 530 can display a running screen of the recording application [FIG. 21 (b)].

Furthermore, the present invention is non-limited by the above description. In a state that the display unit 510 is deactivated, in case of occurrence of a specific event such as a case of recognizing a preset gesture, a case of recognizing a preset movement, and a case of detecting a preset touch input, the controller 530 can launch a recording application.

According to the present embodiment, a recording application can be advantageously launched through a simple input in a state that a display unit is deactivated.

Method of Changing a Setting Value of a Recording Application

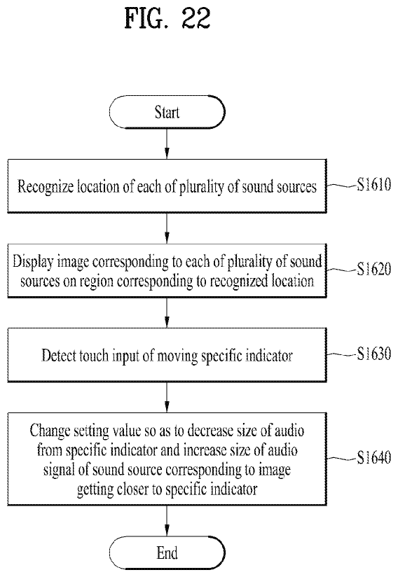

FIG. 22 is a flowchart to describe one example of a method of changing a setting value of a recording application in a mobile terminal according to one embodiment of the present invention.

In response to an execution command of a recording application, the controller 530 can control the display unit 510 to display a screen of the recording application. The controller 530 may receive an input of an audio signal through the audio signal input unit 520 in response to a recording command.

Meanwhile, the controller 530 may recognize whether audio signals of a plurality of sound sources are included in the inputted audio signal.

If the controller 530 recognizes that the audio signals of a plurality of the sound sources are included in the inputted audio signal, the controller 530 may recognize a location of each of a plurality of the sound sources [S1610].

The controller 530 may control the display unit 510 to display an image corresponding to each of a plurality of the sound sources on a region corresponding to the recognized location within the screen [S1620].

Meanwhile, the controller 530 may display a specific indicator related to a change of a setting value of the recording application on the screen.

As detecting a touch input of moving the specific indicator displayed on the screen [S1630], the controller may change a region on which the specific indicator is displayed.

Meanwhile, the controller 530 may change the setting value so that a size of an audio signal of a sound source corresponding to an image getting far away from the specific indicator among the images respectively corresponding to a plurality of the sound sources after the movement of the specific indicator can be decreased. And, the controller 530 may change the setting value so that a size of an audio signal of a sound source corresponding to an image getting closer to the specific indicator among the images respectively corresponding to a plurality of the sound sources after the movement of the specific indicator can be increased [S1640].

According to at least one of the above-described embodiments of the present invention, ordinary persons can advantageously use a function specialized for recording experts with ease. According to at least one of embodiments of the present, usability and user convenience of a recording application can be advantageously enhanced.

The above-described present invention can be implemented in a program recorded medium as computer-readable codes. The computer-readable media may include all kinds of recording devices in which data readable by a computer system are stored. The computer-readable media may include ROM, RAM, CD-ROM, magnetic tapes, floppy discs, optical data storage devices, and the like for example and also include carrier-wave type implementations (e.g., transmission via Internet). Further, the computer may include the controller 180 of the terminal. Therefore, this description is intended to be illustrative, and not to limit the scope of the claims. Thus, it is intended that the present invention covers the modifications and variations of this invention provided they come within the scope of the appended claims and their equivalents.

### MODE FOR INVENTION

Various embodiments for implementing the present invention are described in BEST MODE FOR INVENTION.

### INDUSTRIAL APPLICABILITY

The present invention is used for fields related to a mobile terminal.

The scope of the disclosure should be determined by the appended claims and their legal equivalents, not by the above description, and all changes coming within the meaning and equivalency range of the appended claims are intended to be embraced therein.

1. A mobile terminal, comprising:
a display unit configured to display a screen of a recording application;
an audio signal input unit configured to receive an input of an audio signal in response to a recording command; and
a controller configured to:
display an image corresponding to each of a plurality of sound sources on the screen when the audio signal includes audio signals of the sound sources,
control the display unit to display a specific indicator related to a change of a setting value of the recording application on the screen,
detect a touch input of moving the specific indicator,
change the setting value so as to decrease a size of an audio signal of a sound source corresponding to an image getting away from the specific indicator among images respectively corresponding to the sound sources after movement of the specific indicator, and
change the setting value so as to increase a size of an audio signal of a sound source corresponding to an image getting closer to the specific indicator among the images respectively corresponding to the sound sources after the movement of the specific indicator.

2. The mobile terminal of claim 1, wherein the controller recognizes a location of each of the sound sources and controls the display unit to display an image corresponding to each of the sound sources on a region corresponding to the recognized location within the screen.

3. The mobile terminal of claim 1, wherein the touch input comprises a touch input of touching & dragging the specific indicator.

4. The mobile terminal of claim 3, wherein the controller changes the setting value in response to a drag length of the touch input.

5. The mobile terminal of claim 1, wherein the audio signal input unit comprises a plurality of microphones and wherein the controller changes a gain value of each of a plurality of the microphones when the setting value is changed.

6. The mobile terminal of claim 1, wherein the controller recognizes first information on a volume size of the audio signal of each of the sound sources and determines a size of the image corresponding to each of the sound sources based on the first information.

7. The mobile terminal of claim 1, wherein the setting value comprises at least one of a gain value of a microphone, a value for low frequency noise cancellation, or a value for a maximum volume limit.

8. The mobile terminal of claim 2, wherein the controller recognizes a preset setting value corresponding to a location of each of the sound sources and controls the display unit to display information indicating a location and direction corresponding to the preset setting value on the screen.

9. The mobile terminal of claim 1, wherein the controller recognizes a tone of each of the sound sources and displays an image corresponding to the recognized tone as an image corresponding to each of the sound sources.

10. The mobile terminal of claim 1, wherein the controller recognizes at least one of second information on the number of sound sources and third information on a current situation using the audio signal and controls the display unit to display the second information and the third information on a prescribed region on the screen.

11. A method of controlling an audio recording in a mobile terminal, the method comprising:
displaying a screen of a recording application;
receiving an input of an audio signal in response to a recording command through an audio signal input unit;
displaying an image corresponding to each of a plurality of sound sources on the screen when the audio signal includes audio signals of the sound sources;
displaying a specific indicator related to a change of a setting value of the recording application on the screen;
detecting a touch input of moving the specific indicator;
changing the setting value so as to decrease a size of an audio signal of a sound source corresponding to an image getting away from the specific indicator among images respectively corresponding to the sound sources after movement of the specific indicator; and
changing the setting value so as to increase a size of an audio signal of a sound source corresponding to an image getting closer to the specific indicator among the images respectively corresponding to the sound sources after the movement of the specific indicator.

12. The method of claim 11, the displaying the image, comprising:
recognizing a location of each of the sound sources; and
displaying an image corresponding to each of the sound sources on a region corresponding to the recognized location within the screen.

13. The method of claim 11, wherein the touch input comprises a touch input of touching & dragging the specific indicator.

14. The method of claim 13, wherein the setting value is changed in response to a drag length of the touch input.

15. The method of claim 11, further comprising changing a gain value of each of a plurality of microphones included in the audio signal input unit according to the changed setting value.

16. The method of claim 11, further comprising:
recognizing first information on a volume size of the audio signal of each of the sound sources; and
determining a size of the image corresponding to the sound sources based on the first information.

17. The method of claim 11, wherein the setting value comprises at least one of a gain value of a microphone, a value for low frequency noise cancellation, or a value for a maximum volume limit.

18. The method of claim 12, further comprising:
recognizing a preset setting value corresponding to a location of each of a plurality of the sound sources; and
displaying information indicating a location and direction corresponding to the preset setting value on the screen.

19. The method of claim 11, the displaying the image, comprising:
recognizing a tone of each of the sound sources; and displaying an image corresponding to the recognized tone as an image corresponding to each of the sound sources.

20. The method of claim 11, further comprising:
recognizing at least one of second information on the number of sound sources and third information on a current situation using the audio signal; and
displaying the second information and the third information on a prescribed region on the screen.
